(19) United States
(12) Patent Application Publication
(10) Pub. No.: US 2026/0033097 A1
(43) Pub. Date: Jan. 29, 2026

(54) DISPLAY DEVICE

(71) Applicant: LG Display Co., Ltd., Seoul (KR)

(72) Inventors: Inhwan GU, Seoul (KR); Hyesun JUNG, Seoul (KR); Jaebin SONG, Seoul (KR)

(73) Assignee: LG Display Co., Ltd., Seoul (KR)

(21) Appl. No.: 19/255,502

(22) Filed: Jun. 30, 2025

(30) Foreign Application Priority Data
Jul. 26, 2024 (KR) 10-2024-0099388

(51) Int. Cl. H10H 29/853; G09G 3/32; H10H 29/855

(52) U.S. Cl. CPC H10H 29/853; H10H 29/855; G09G 3/32; G09G 2300/0861

(57) ABSTRACT

A display device can include a substrate, a plurality of driving chips disposed on the substrate, a plurality of light-emitting elements disposed on one of the plurality of driving chips and being electrically connected to the one driving chip, an optical insulating layer covering the plurality of light-emitting elements, a first overcoating layer disposed on the optical insulating layer, and a second overcoating layer disposed on the first overcoating layer. The refractive index of the first overcoating layer can be lower than the refractive index of the second overcoating layer.

### CROSS-REFERENCE TO RELATED APPLICATION

This application claims priority to Korean Patent Application No. 10-2024-0099388 filed on Jul. 26, 2024 in the Korean Intellectual Property Office, which is hereby expressly incorporated by reference in its entirety into the present application.

### BACKGROUND

### Field

The present disclosure relates to a display device.

### Description of the Related Art

Display devices are applied to various electronic devices such as TVs, mobile phones, laptops, and tablets.

The display devices can be classified into organic light-emitting display (OLED) apparatuses having self-luminous properties, and liquid crystal display (LCD) apparatuses requiring a separate light source.

Recently, display devices including a light-emitting diode (LED) (hereinafter, referred to as a “light-emitting element”) are attracting attention as next-generation display devices. Since the light-emitting element is not configured with organic materials but inorganic materials, it can light up faster than the liquid crystal display device or the organic light-emitting display device, have excellent light-emitting efficiency, and display high-brightness images.

### SUMMARY OF THE DISCLOSURE

Generally, a display device can include a polarizing layer to improve outdoor visibility. Light emitted from a light source within the display device can be emitted to the outside through the polarizing layer. Some of the light incident on the polarizing layer can be perished without being emitted to the outside due to a total internal reflection.

As the amount of light undergoing the total internal reflection in the polarizing layer increases, the amount of perished light increases and the light extraction efficiency decreases. Therefore, in order to reduce the amount of light perished in the polarizing layer, it is necessary to reduce the amount of light undergoing the total internal reflection in the polarizing layer.

As an example, a method of controlling the angle of incidence of light incident on the polarizing layer can be taken into account. Specifically, since the total reflection occurs for incident light having an angle of incidence greater than the total reflection angle at the polarizing layer, a method of reducing the angle of incidence of light toward the polarizing layer to less than the total reflection angle can be taken into account.

To this end, light with a large angle of incidence can be subjected to total reflection in advance between the polarizing layer and the light source before the light reaches the polarizing layer. Light that has been subjected to the total reflection in advance can be incident on the polarizing layer at angles adjusted to be smaller than the total reflection angle at the polarizing layer.

By reducing in this way the proportion at which the total reflection occurs at the polarizing layer, the amount of light emitted to the outside through the polarizing layer can be increased, thereby increasing the light extraction efficiency.

For example, by disposing a low refractive index layer between the light source and the polarizing layer, the angle of incidence of light incident on the polarizing layer can be controlled. However, in the photo process for forming the low refractive index layer, the curing may not take place properly along the edge portion of the low refractive index layer, which can lead to the occurrence of an undercut section. The undercut sections, which have occurred like this, can become a moisture penetration path or a cause of problems such as cracks.

In other words, the method of disposing the low refractive index layer on the light source can be taken into account to improve the light extraction efficiency; however, the disposition of the low refractive index layer can lead to another problem in that the undercut section can occur along the edge portion of the low refractive index layer.

In view of the above issues associated with the related art, the inventors of the present disclosure have, through a range of experiments, invented a display device with increased light extraction efficiency and highly resistant to occurrence of undercut sections.

An object to be accomplished according to embodiments of the present disclosure is to provide a display device with improved light extraction efficiency and high reliability.

In addition, another object to be accomplished according to embodiments of the present disclosure is to provide a display device capable of improving light extraction efficiency.

In addition, still another object to be accomplished according to embodiments of the present disclosure is to provide a display device including a novel configuration capable of preventing an undercut section from becoming a cause of a defect.

In addition, yet another object to be accomplished according to embodiments of the present disclosure is to provide a display device with increased bonding strength between insulating layers configured with different materials.

The present disclosure can have other purposes besides the aforementioned one, which are clearly recognizable to a person skilled in the art from the description below.

A display device according to embodiments of the present disclosure can include a substrate, a plurality of driving chips disposed on the substrate, a plurality of light-emitting elements disposed on the driving chip and being electrically connected to the driving chip, an optical insulating layer covering the plurality of light-emitting elements, a first overcoating layer disposed on the optical insulating layer, and a second overcoating layer disposed on the first overcoating layer. A refractive index of the first overcoating layer can be lower than a refractive index of the second overcoating layer.

A display device according to embodiments of the present disclosure can include a substrate, a plurality of driving chips disposed on the substrate, a plurality of light-emitting elements disposed on the driving chip and being electrically connected to the driving chip, an optical insulating layer covering the plurality of light-emitting elements, a first overcoating layer positioned on the optical insulating layer and including an undercut section formed along an edge portion thereof, and a second overcoating layer filling the undercut section.

According to an embodiment of the present disclosure, the proportion of light undergoing total reflection at the interface between the upper diffusion film and the first overcoating layer having a low refractive index can be increased. Thereby, the angle of incidence of light incident on the polarizing layer can be made smaller than the total reflection angle, thus improving the light extraction efficiency. The improved light extraction efficiency can lead to the provision of a display device capable of being driven with low power consumption.

In addition, according to an embodiment of the present disclosure, the second overcoating layer having a high refractive index can be disposed in the undercut section formed on the edge portion of the first overcoating layer having a low refractive index, thereby preventing or reducing the occurrence of the undercut section becoming a problem. As a result, the reliability of the display device can be improved.

In addition, according to an embodiment of the present disclosure, the second overcoating layer having a high refractive index can be disposed to surround the edge portion of the first overcoating layer having a low refractive index, thereby increasing the bonding strength between the insulating layers configured with different materials. As a result, it is possible to prevent the occurrence of defects which may be caused by the delamination between the insulating layers.

In addition, according to an embodiment of the present disclosure, the second overcoating layer having a high refractive index can be disposed on the uppermost portion of the organic layers, thereby preventing an undercut section from occurring at the edge portion of the second overcoating layer. As a result, the reliability of the display device can be improved.

Accordingly, an embodiment of the present disclosure can produce effects such as not only the improved light extraction efficiency in the display area, but also the implementation of a display device having high reliability.

The present disclosure can provide other effects besides the ones described above, which are clearly recognizable to a person skilled in the art from the claims.

### BRIEF DESCRIPTION OF DRAWINGS

The present disclosure will become more fully understood from the detailed description given hereinbelow and the accompanying drawings which are given by way of illustration only, and thus are not limitative of the present disclosure.

FIG. 1 is an exploded perspective view of a display device according to one or more embodiments of the present disclosure.

FIG. 2 is a plan view of a display device according to an embodiment of the present disclosure.

FIG. 3 is an enlarged view of a display device according to an embodiment of the present disclosure.

FIG. 4 is a diagram showing a circuit structure according to an embodiment of the present disclosure.

FIG. 5 is a plan view of a display device according to an embodiment of the present disclosure.

FIG. 6 is a plan view of a display device according to an embodiment of the present disclosure.

FIG. 7 is a plan view of a display device according to an embodiment of the present disclosure.

FIG. 8 is a cross-sectional view of a display device according to an embodiment of the present disclosure.

FIG. 9 is a cross-sectional view of a display device according to an embodiment of the present disclosure.

FIGS. 10 to 13 are views illustrating devices to which display devices according to embodiments of the present disclosure are applied.

FIG. 14 is a plan view of a display device according to another embodiment of the present disclosure.

FIG. 15 is a plan view showing an area where one of the plurality of pixel driving circuits of FIG. 14 is disposed.

FIG. 16 is a view showing a touch operation of a display device according to another embodiment of the present disclosure.

FIG. 17 is a diagram illustrating, by way of example, a signal waveform diagram when driving a display device according to an embodiment of the present disclosure.

FIG. 18 is an enlarged plan view showing area 7 in FIG. 15 according to another embodiment of the present disclosure.

FIG. 19 is a cross-sectional view taken along line 8-8 in FIG. 18.

FIG. 20 is a cross-sectional view showing area 9 in FIG. 19.

FIG. 21 is a plan view showing the bonding portion in FIG. 20.

FIG. 22 is a cross-sectional view taken along line 11-11 in FIG. 14.

FIG. 23 is an enlarged cross-sectional view of a tapered area according to another embodiment of the present disclosure.

FIG. 24 is a cross-sectional view taken along cut line 13-13 in FIG. 14, of a display device according to another embodiment of the present disclosure.

FIG. 25 is a view illustrating the mechanism by which an undercut section occurs.

FIG. 26 is a plan view showing a display panel of a display device according to another embodiment of the present disclosure.

FIG. 27 is a cross-sectional view taken along cut line 16-16 in FIG. 26.

FIG. 28 is a cross-sectional view taken along cut line 17-17 in FIG. 26.

FIG. 29 is a plan view showing a display panel of a display device according to another embodiment of the present disclosure.

FIG. 30 is a cross-sectional view taken along cut line 19-19 in FIG. 29.

FIG. 31 is a cross-sectional view taken along cut line 20-20 in FIG. 29.

### DETAILED DESCRIPTION OF THE EMBODIMENTS

Advantages and features of the present disclosure, and a method of achieving the advantages and features will become apparent when referring to the following embodiments described later in detail together with the accompanying drawings. However, the present disclosure is not limited to the embodiments as disclosed below, but can be embodied in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating embodiments of the present disclosure are illustrative, and the present disclosure is not limited thereto. Throughout the detailed description, like reference symbols refer to like components. Further, in describing the present disclosure, if it is determined that a detailed description of a related known technology can unnecessarily obscure the gist of the present disclosure, the detailed description thereof will be omitted. When the terms “comprise”, “include,” “have,” “configure,” and the like are used in this disclosure, the presence or addition of other element can be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “under”, and “next to”, one or more other elements can be interposed between the two elements unless the term “just”, “directly”, or “close” is used.

In describing a temporal relationship, for example, when the temporal order is described as “after”, “subsequent”, “next”, and “before”, the case which is not continuous can also be included unless the term “just” or “directly” is used.

It will be understood that, although the terms “first”, “second”, etc. can be used herein to describe various elements, these elements should not be limited by these terms. These terms are only used to distinguish one element from another element. So, a first element referred to in the following description can represent a second element, without departing from the scope of the technical idea of the present disclosure. In describing components herein, terms such as first, second, A, B, (a), or (b) can be used. These terms are only intended to distinguish one component from another, and do not limit the nature, order, sequence, or number of the components.

When a component is described as being “connected to,” “coupled to,” “access to,” or “attached to” another component, such component can be directly connected to, coupled to, contact with, or attached to the other component, and, however, it should be understood that they can be indirectly connected to, coupled to, access to, or attached to each other with still another component interposed therebetween, unless explicitly stated to the contrary.

When a component or layer is described as “being in contact with,” or “overlapping with” another component or layer, such component or layer can directly be in contact with or overlap with the other component or layer, and, however, it should be understood that they can also indirectly be in contact with or overlap with each other with still another component or layer interposed between, unless explicitly stated to the contrary.

The expression “at least one” should be understood to include any combination of one or more of the associated components. For example, the meaning of “at least one of the first, second, and third components” can include not only the first, second, or third component, but also any combination of two or more of the first, second, and third components.

The terms “first direction”, “second direction”, “third direction”, “X-axis direction”, “Y-axis direction”, and “Z-axis direction” should not be interpreted as merely geometric relationships in which the relationship between them is perpendicular to each other, but can mean a wider directionality within the range in which the configuration of the present disclosure can act functionally. Further, the term “can” fully encompasses all the meanings and coverages of the term “may” and vice versa.

The individual features of the various embodiments of the present disclosure can be coupled or combined with each other in part or in whole to be interconnected and operated in a variety of technical ways, and each embodiment can be implemented independently of each other or implemented together in an associative relationship.

Hereinafter, various embodiments of the present disclosure will be described in detail with reference to the accompanying drawings. All the components of each display device according to all embodiments of the present disclosure are operatively coupled and configured.

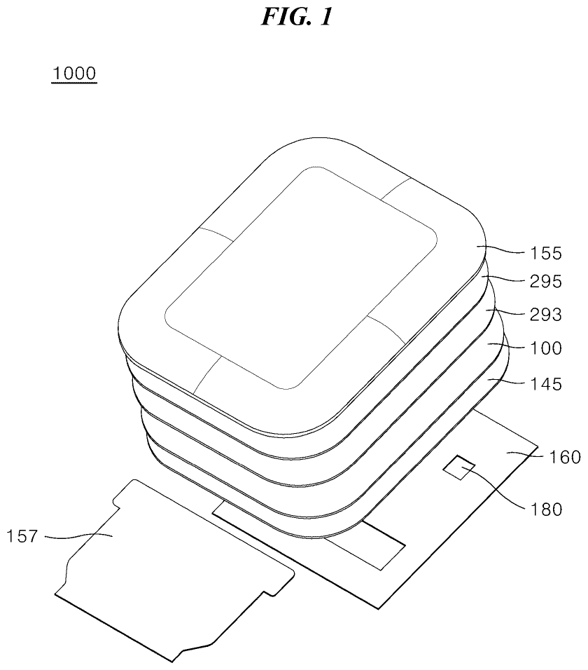

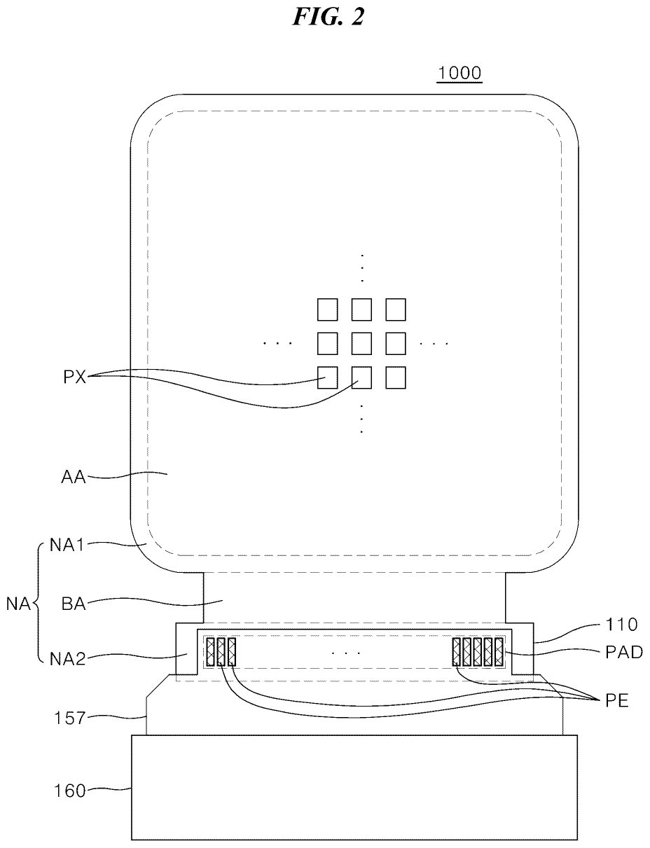

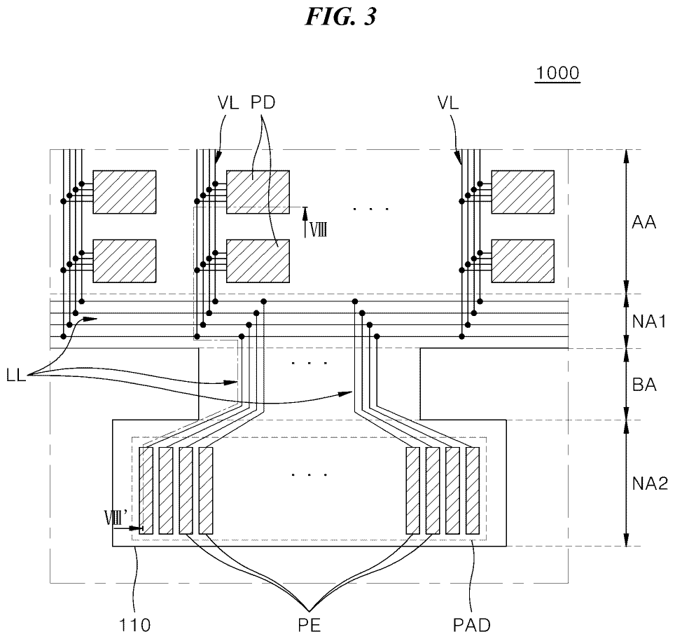

FIG. 1 is a perspective view showing a display device according to one or more embodiments of the present disclosure. FIG. 2 is a plan view of a display device according to an embodiment of the present disclosure. FIG. 3 is an enlarged view of a display device according to an embodiment of the present disclosure.

Referring to FIGS. 1 to 3, a display device 1000 according to an embodiment of the present disclosure can include a display panel 100, a polarizing layer 293, an adhesive layer 295, a cover member 155, a support substrate 145, a flexible circuit board 157, and a printed circuit board 160.

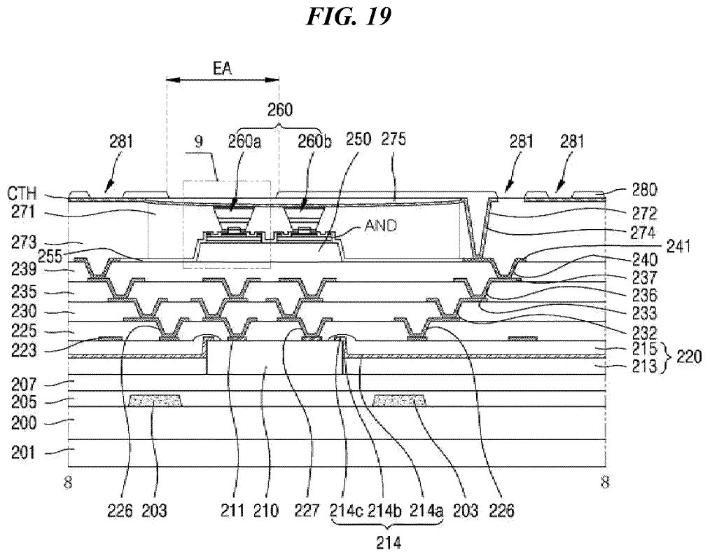

For example, the display device 1000 can include a substrate 110. The substrate 110 can be a member that supports other components of the display device 1000. The substrate 110 can be configured with an insulating material. For example, the substrate 110 can include the material of the substrate 200 of FIG. 19 to be described later.

The display panel 100 can implement information, video, and/or images to be provided to a user. For example, the display panel 100 can include a display area AA (or active area) and a non-display area NA (or non-active area). For example, the substrate 110 can include the display area AA and the non-display area NA. The description for the display area AA and non-display area NA are not limited to the substrate 110, but can be applicable throughout the display device 1000.

The display area AA can be an area where an image is displayed. The display area AA can include a plurality of pixels PX. Each of the plurality of pixels PX can be constituted with a plurality of sub-pixels. At each of the plurality of sub-pixels a plurality of light-emitting elements can be disposed. The plurality of light-emitting elements can be configured differently depending on the kinds of display device 1000. For example, in a case where the display device 1000 is an inorganic light-emitting display device, the light-emitting element can be an LED (Light-emitting Diode), a Micro LED (Micro Light-emitting Diode), or a Mini LED (Mini Light-emitting Diode), but the embodiments of the present disclosure are not limited thereto.

The non-display area NA can be an area where an image is not displayed. In the non-display area NAA, various wirings and circuits for driving a plurality of pixels PX in the display area AA can be disposed. For example, in the non-display area NA, there can be disposed a pad part PAD on which various wirings and driving circuits can be mounted and to which integrated circuits and printed circuits are connected, but the embodiments of the present disclosure are not limited thereto.

For example, the driving circuit can be a data driving circuit and/or a gate driving circuit, but the embodiments of the present disclosure are not limited thereto. In the non-display area NA, there can be disposed wirings through which control signals for controlling the driving circuits are supplied. For example, the control signal can include various timing signals including synchronization signals, an input data enable signal, and a clock signal, but the embodiments of the present disclosure are not limited thereto. The control signal can be received through the pad part PAD. For example, in the non-display area NA, there can be disposed link wirings LL for transmitting a signal. For example, driving components such as the flexible circuit board 157 and the printed circuit board 160 can be connected to the pad part PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA can be an area which is bendable and extends from at least one of a plurality of sides of the first non-display area NA1. The second non-display area NA2 can be an area which extends from the bending area BA, and in which the pad part PAD can be disposed. For example, the bending area BA can be in a bent state, and the remaining area of the substrate 110 except the bending area BA can be in a flat state. In this case, as the bending area BA is bent, the second non-display area NA2 can be located on the rear surface of the display area AA. However, the embodiments of the present disclosure are not limited thereto.

The display area AA of the substrate 110 or the display device 1000 can be configured in various shapes depending on the designs of the display device 1000. For example, the display area AA can be configured in a rectangular shape with four rounded corners, but the embodiments of the present disclosure are not limited thereto. For another example, the display area AA can be configured in a rectangular shape with four right angles, a circular shape, or the like, but the embodiments of the present disclosure are not limited thereto.

According to the present disclosure, the width of the second non-display area NA2 in which a plurality of pad electrodes PE are disposed can be greater than the width of the bending area BA in which only the plurality of link wirings LL are disposed. Additionally, the width of the display area AA in which the plurality of sub-pixels are disposed can be greater than the width of the bending area BA in which only the plurality of link wirings LL are disposed. Although the width of the bending area BA is depicted in the drawing as being smaller than the widths of other areas of the substrate 110, the shape of the substrate 110 including such bending area BA is given only as an example, and the embodiments of the present disclosure are not limited thereto.

Referring to FIG. 3, in the display area AA, there can be disposed a plurality of pixel driving circuits PD. The plurality of pixel driving circuits PD can be circuits for driving light-emitting elements of a plurality of sub-pixels. Each of the plurality of pixel driving circuits PD can include a plurality of transistors including a driving transistor, a storage capacitor and the like, and can control the light-emitting operation of the plurality of light-emitting elements by supplying a control signal, power, and a driving current to the light-emitting elements of the plurality of sub-pixels. For example, a pixel driving circuit PD can include a power wiring and a signal wiring for controlling the on/off and/or light-emitting time of a light-emitting element. For example, the plurality of pixel driving circuits PD can be driving drivers manufactured on a semiconductor substrate using a MOSFET (Metal-oxide-silicon field effect transistor) manufacturing process, but the embodiments of the present disclosure are not limited thereto. The driving driver can include a plurality of pixel driving circuits PD, and can drive a plurality of sub-pixels. For example, the plurality of pixel driving circuits PD can include a micro driver μDriver, but the embodiments of the present disclosure are not limited thereto. For example, the plurality of pixel driving circuits PD can include a driving chip, but the embodiments of the present disclosure are not limited thereto.

Referring to FIG. 1 together, the flexible circuit board 157 and the printed circuit board 160 can be disposed at the lower side of the display panel 100. The flexible circuit board 157 and the printed circuit board 160 can be disposed at least on one edge of the display panel 100, but the embodiments of the present disclosure are not limited thereto. The flexible circuit board 157 can be attached to the display panel 100 at its one side, and to the printed circuit board 160 at another side thereof, but the embodiments of the present disclosure are not limited thereto. The flexible circuit board 157 can be configured with a flexible film, but the embodiments of the present disclosure are not limited thereto.

In the second non-display area NA2, the pad part PAD can be disposed, which includes the plurality of pad electrodes PE. To the pad part PAD a driving component including one or more flexible circuit boards (or flexible films) 157 and the printed circuit boards 160 can be attached or bonded. The plurality of pad electrodes PE of the pad part PAD can be electrically connected to one or more flexible circuit boards (or flexible films) 157 to transmit various signals or power from the printed circuit board 160 and the flexible circuit board (or flexible film) 157 to the plurality of pixel driving circuits PD in the display area AA.

The flexible circuit board (or flexible film) 157 can be configured with a film whose base film has a flexibility and is provided with various components disposed thereon. For example, the flexible circuit board (or flexible film) 157 can be provided with a driving IC such as a gate driving IC or a data driving IC disposed thereon, but the embodiments of the present disclosure are not limited thereto. The driving IC can be a kind of a component that processes data and driving signals for displaying an image. The driving IC can be disposed in a manner such as a Chip On Glass (COG), a Chip On Film (COF), or a Tape Carrier Package (TCP) depending on the mounting method, but the embodiments of the present disclosure are not limited thereto. The flexible circuit board (or flexible film) 157 can be attached or bonded onto the plurality of pad electrodes PE via a conductive adhesive layer, but the embodiments of the present disclosure are not limited thereto.

The printed circuit board 160 can be a kind of a component electrically connected to one or more flexible circuit boards (or flexible films) 157 to supply signals to the driving IC. The printed circuit board 160 can be disposed at one side of the flexible circuit board (or flexible film) 157 to be electrically connected to the flexible circuit board (or flexible film) 157. On the printed circuit board 160, there can be disposed a range of components for supplying various signals to the driving IC. For example, on the printed circuit board 160, a variety of components, including a timing controller, a power supply, a memory, a processor, or the like, can be disposed. For example, the printed circuit board 160 can be provided with a power management integrated circuit PMIC, but the embodiments of the present disclosure are not limited thereto.

The printed circuit board 160 can include at least one hole 180, but the embodiments of the present disclosure are not limited thereto. In an area corresponding to at least one hole 180, there can be disposed an internal component detecting ambient light, temperature or the like, which can be provided with a plurality of sensors. For example, the internal component can include an ambient light sensor (ALS) or a temperature sensor, but embodiments of the present disclosure are not limited thereto. For example, the hole 180 can be a kind of a permeable hole, but the embodiments of the present disclosure are not limited thereto.

Referring to FIG. 1, the polarizing layer 293 can be disposed on the display panel 100. The polarizing layer 293 can prevent or alleviate a phenomenon in which the light generated by an external light source enters the inside of the display panel 100 and affects the light-emitting element or the like.

The cover member 155 can be disposed on the polarizing layer 293. The cover member 155 can be a member for protecting the display panel 100. The adhesive layer 295 can be disposed between the polarizing layer 293 and the cover member 155. By the adhesive layer 295 the cover member 155 can be attached to the display panel 100. The adhesive layer 295 can include an optically clear adhesive (OCA), an optically clear resin (OCR), a pressure sensitive adhesive (PSA), or the like, but the embodiments of the present disclosure are not limited thereto.

The support substrate 145 can be disposed between the display panel 100 and the printed circuit board 160. The support substrate 145 can reinforce the rigidity of the display panel 100. The support substrate 145 can be a kind of a back plate, but the embodiments of the present disclosure are not limited thereto.

Referring to FIGS. 1 to 3, the plurality of link wirings LL can be disposed in the non-display area NA. The plurality of link wirings LL can be wirings that transmit various signals from one or more flexible circuit boards (or flexible films) 157 and the printed circuit boards 160 to the display area AA. The plurality of link wirings LL can extend from the plurality of pad electrodes PE in the second non-display area NA2 toward the bending area BA and the first non-display area NA1 to be electrically connected to a plurality of driving wirings VL in the display area AA. The plurality of pixel driving circuits PD can be driven by receiving signals from one or more flexible circuit boards (or flexible films) 157 and printed circuit boards 160 through the driving wirings VL in the display area AA and the link wirings LL in the non-display area NA.

For example, the plurality of driving wirings VL can be wirings for transmitting signals output from the flexible circuit board (or flexible film) 157 and the printed circuit board 160 to the plurality of pixel driving circuits PD together with the plurality of link wirings LL. The plurality of driving wirings VL can be disposed in the display area AA to be electrically connected to each of the plurality of pixel driving circuits PD. The plurality of driving wirings VL can extend from the display area AA toward the non-display area NA to be electrically connected to the plurality of link wirings LL. Therefore, the signals output from the flexible circuit board (or flexible film) 157 and the printed circuit board 160 can be transmitted to each of the plurality of pixel driving circuits PD through the plurality of link wirings LL and the plurality of driving wirings VL.

When the bending area BA is bent, portions of the plurality of link wirings LL can be also bent together. Stress can be concentrated on a portion of the bent link wiring LL, which can cause cracks to occur in the link wiring LL. So, the plurality of link wirings LL can be configured with a conductive material having excellent ductility to reduce the cracks when the bending area BA is bent. For example, the plurality of link wirings LL can be configured with a conductive material having excellent ductility, such as gold Au, silver Ag, aluminum Al or the like, but the embodiments of the present disclosure are not limited thereto. Alternatively, the plurality of link wirings LL can be configured with one of various conductive materials used in the display area AA. For example, the plurality of link wirings LL can be configured with molybdenum (Mo), chromium (Cr), titanium (Ti), nickel (Ni), neodymium (Nd), copper (Cu), and an alloy of silver (Ag) and magnesium (Mg), or any alloy thereof, but the embodiments of the present disclosure are not limited thereto. The plurality of link wirings LL can be configured in a multilayer structure including various conductive materials. For example, the plurality of link wirings LL can be configured in a triple layer structure of titanium (Ti)/aluminum (Al)/titanium (Ti), but the embodiments of the present disclosure are not limited thereto.

The plurality of link wirings LL can be configured in various shapes to reduce stress. At least a portion of the plurality of link wirings LL disposed on the bending area BA can extend in the same direction as the extension direction of the bending area BA, or in a direction different from the extension direction of the bending area BA, to reduce stress. For example, in a case where the bending area BA extends in one direction from the first non-display area NA1 toward the second non-display area NA2, at least a portion of the link wiring LL disposed on the bending area BA can extend in a direction transverse to the one direction. As another example, at least a portion of the plurality of link wirings LL can be configured in patterns of various shapes. For example, at least a portion of the plurality of link wirings LL disposed on a bending area BA can have a shape in which a conductive pattern having at least one shape of a diamond shape, a rhombus shape, a trapezoidal wave shape, a triangular wave shape, a sawtooth wave shape, a sine wave shape, a circular shape, and an omega (52) shape can be repeatedly disposed, but the embodiments of the present disclosure are not limited thereto.

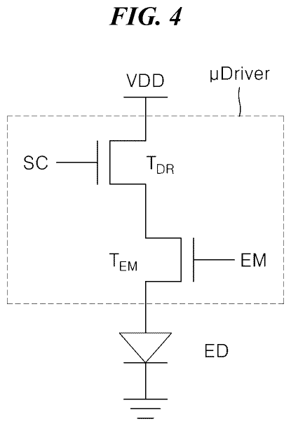

FIG. 4 is a diagram showing a circuit structure according to an embodiment of the present disclosure.

Referring to FIG. 4, one light-emitting element ED is, by way of example, connected to a micro driver μDriver; however this is not exhaustive. For example, one microdriver μDriver can control a plurality of pixels arranged on the substrate in sixteen columns by sixteen rows (16×16). The plurality of pixels can include a plurality of light-emitting elements ED.

One microdriver Driver can be implemented in the form of a chip. For example, the microdriver μDriver implemented in the form of a chip can include circuits of a driving transistor T_{DR} and a light-emitting transistor T_{EM}.

For example, the driving transistor T_{DR} in the micro driver μDriver can have a first electrode to which a high-potential power supply voltage VDD is applied, a second electrode to which a first electrode of the light-emitting transistor T_{EM} is connected, and a gate electrode to which a scan signal SC is applied. The scan signal SC applied to the gate electrode of the driving transistor T_{DR} can be a direct current (DC) power source, and a fixed reference voltage (Vref) can be applied every frame, but the embodiments of the present disclosure are not limited thereto.

The light-emitting transistor T_{EM} can have the first electrode to which the second electrode of the driving transistor T_{DR} is connected, a second electrode to which the light-emitting element ED is connected, and a gate electrode to which a light-emitting signal EM is applied. The light-emitting signal EM applied to the gate electrode of the light-emitting transistor T_{EM} can be a pulse width modulation (PWM) signal that varies every frame, but the embodiments of the present disclosure are not limited thereto.

The light-emitting element ED can have the first electrode connected to the second electrode of the light-emitting transistor T_{EM}, and a second electrode connected to ground. For example, the first electrode can be an anode electrode, and the second electrode can be a cathode electrode, but the embodiments of the present disclosure are not limited thereto.

The driving transistor T_{DR} and the light-emitting transistor T_{EM} can each be an n-type or a p-type transistor.

In the micro driver μDriver, the driving transistor T_{DR} can be turned on by the scan signal SC applied from the timing controller T-CON, and the light-emitting transistor T_{EM} can be turned on by the light-emitting signal EM. By this, a driving current can be applied to the light-emitting element ED via the driving transistor T_{DR} and the light-emitting transistor T_{EM} by the high-potential power supply voltage VDD applied to the first electrode of the driving transistor T_{DR}, thereby causing the light-emitting element ED to emit light.

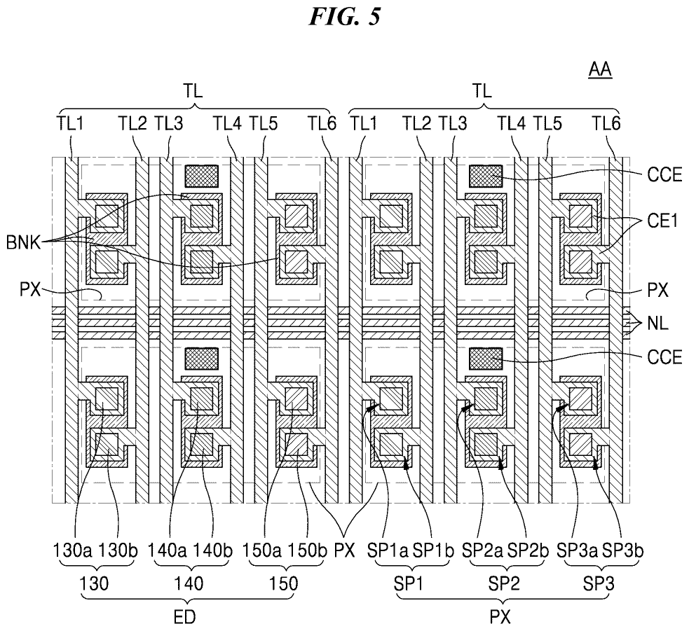

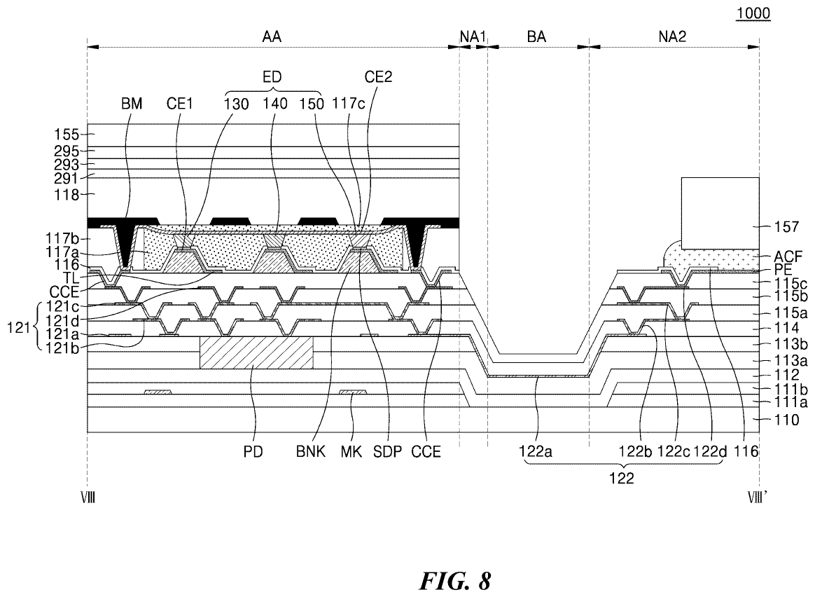

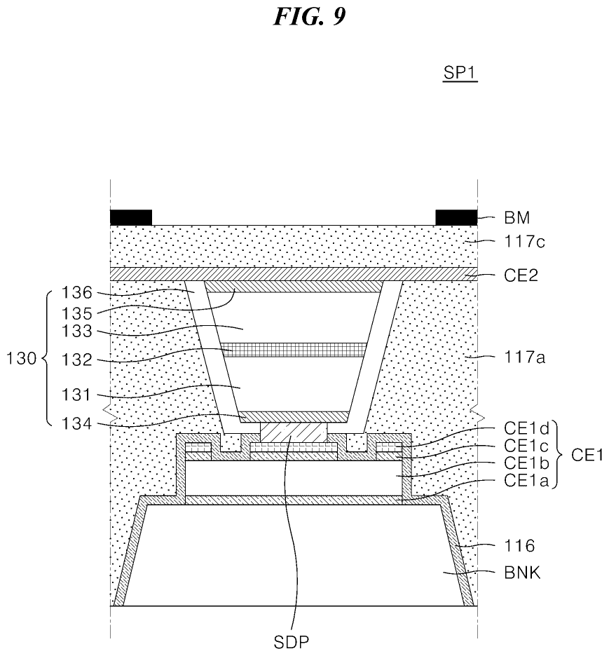

FIGS. 5 to 7 are plan views of a display device according to an embodiment of the present disclosure. FIGS. 8 and 9 are cross-sectional views of a display device according to an embodiment of the present disclosure.

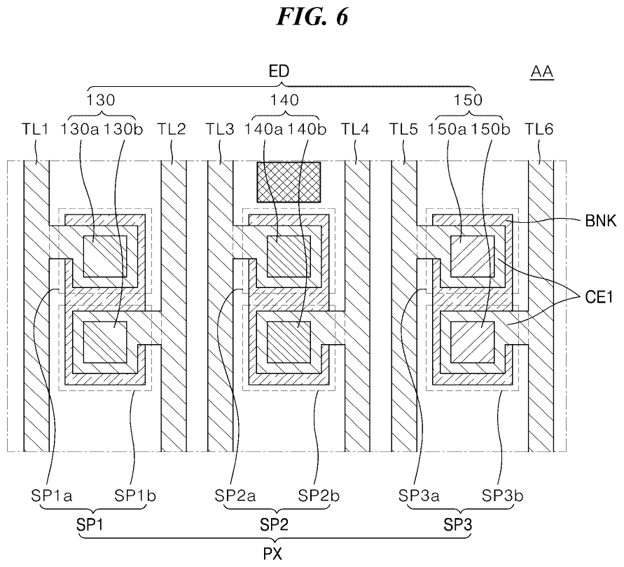

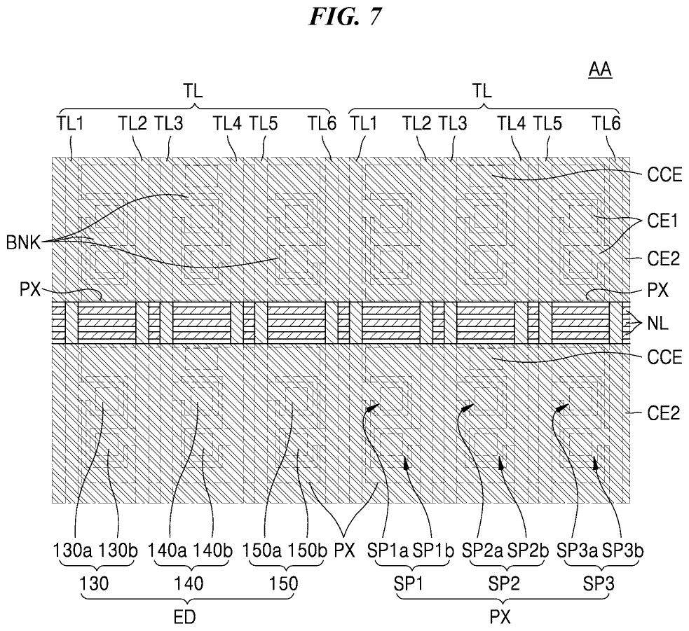

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA, the bending area BA, and the second non-display area NA2. For example, FIG. 9 is a cross-sectional view of a display area including one sub-pixel SP1. In FIGS. 5 and 6, a plurality of signal wirings TL, a plurality of communication wirings NL, a plurality of first electrodes CE1, a plurality of banks BNK, and a plurality of light-emitting elements ED are illustrated, but the embodiments of the present disclosure are not limited thereto. FIG. 7 is an enlarged plan view in which a plurality of second electrodes CE2 are additionally disposed to FIG. 5.

Referring to FIGS. 5, 6, and 9, a plurality of pixels PX configured with a plurality of sub-pixels can be disposed in the display area AA. Each of the plurality of sub-pixels can include a light-emitting element ED, and can independently emit light. The plurality of sub-pixels can be disposed in a matrix form, forming a plurality of rows and a plurality of columns, but the embodiments of the present disclosure are not limited thereto.

The plurality of sub-pixels can include a first sub-pixel SP1, a second sub-pixel SP2, and a third sub-pixel SP3. For example, one of the first sub-pixel SP1, the second sub-pixel SP2 and the third sub-pixel SP3 can be a red sub-pixel, another thereof can be a green sub-pixel, and the remaining one thereof can be a blue sub-pixel. The types of the plurality of sub-pixels are given only as an example, and the embodiments of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. The pair of first sub-pixels SP1 can be configured with a first-first sub-pixel SP1a and a first-second sub-pixel SP1b. The pair of second sub-pixels SP2 can be configured with a second-first sub-pixel SP2a and a second-second sub-pixel SP2b. The pair of third sub-pixels SP3 can be configured with a third-first sub-pixel SP3a and a third-second sub-pixel SP3b. For example, one pixel PX can include the first-first sub-pixel SP1a and the first-second sub-pixel SP1b, the second-first sub-pixel SP2a and the second-second sub-pixel SP2b, and the third-first sub-pixel SP3a and the third-second sub-pixel SP3b, but the embodiments of the present disclosure are not limited thereto.

The plurality of sub-pixels constituting one pixel PX can be arranged in various ways. For example, in one pixel PX, the pair of first sub-pixels SP1 can be disposed in the same column, the pair of second sub-pixels SP2 can be disposed in the same column, and the pair of third sub-pixels SP3 can be disposed in the same column. The first sub-pixel SP1, the second sub-pixel SP2, and the third sub-pixel SP3 can be disposed in the same row. The number and arrangement of the plurality of sub-pixels constituting one pixel PX are given only as an example, and the embodiments of the present disclosure are not limited thereto.

The plurality of signal wirings TL can be disposed in the area between a plurality of sub-pixels. The plurality of signal wirings TL can extend in the column direction between the plurality of sub-pixels. The plurality of signal wirings TL can be wirings that transmit the anode voltage from the pixel driving circuit PD to the plurality of sub-pixels. For example, the plurality of signal wirings TL can be electrically connected to the plurality of pixel driving circuits PD and first electrodes CE1s of the plurality of sub-pixels. The anode voltage output from the pixel driving circuit PD can be transmitted to the first electrodes CE1s of the plurality of sub-pixels through the plurality of signal wirings TL. For example, the first electrode CE1 can be an electrode electrically connected to an anode electrode 134 of the light-emitting element ED. By this, the anode voltage from the signal wiring TL can be transmitted to the anode electrode 134 of the light-emitting element ED through the first electrode CE1.

Therefore, instead of forming a plurality of transistors and storage capacitors in each of the plurality of sub-pixels, by using the pixel driving circuit PD in which a plurality of pixel circuits are integrated, the structure of the display device 1000 can be simplified. In addition, since the circuits disposed in each of the plurality of sub-pixels are integrated into one pixel driving circuit PD, high-efficiency and low-power driving can be realized.

The plurality of signal wirings TL can include a first signal wiring TL1, a second signal wiring TL2, a third signal wiring TL3, a fourth signal wiring TL4, a fifth signal wiring TL5, and a sixth signal wiring TL6. Each of the first signal wiring TL1 and the second signal wiring TL2 can be electrically connected to each of the pair of first sub-pixels SP1. Each of the third signal wiring TL3 and the fourth signal wiring TL4 can be electrically connected to each of the pair of second sub-pixels SP2. Each of the fifth signal wiring TL5 and the sixth signal wiring TL6 can be electrically connected to each of the pair of third sub-pixels SP3.

The first signal wiring TL1 can be disposed at one side of the pair of first sub-pixels SP1, and the first signal wiring TL1 can be disposed at the other side of the pair of first sub-pixels SP1. The first signal wiring TL1 can be electrically connected to the first electrode CE1 of one of the first sub-pixels SP1 of the pair of first sub-pixels SP1, for example, the first-first sub-pixel SP1a. The second signal wiring TL2 can be electrically connected to the first electrode CE1 of the remaining first sub-pixel SP1 of the pair of first sub-pixels SP1, for example, the first-second sub-pixel SP1b.

The third signal wiring TL3 can be disposed at one side of the pair of second sub-pixels SP2, and the fourth signal wiring TL4 can be disposed at the other side of the pair of second sub-pixels SP2. For example, the third signal wiring TL3 can be disposed neighboring the second signal wiring TL2. The third signal wiring TL3 can be electrically connected to the first electrode CE1 of one of the second sub-pixels SP2 of the pair of second sub-pixels SP2, for example, the second-first sub-pixel SP2a. The fourth signal wiring TL4 can be electrically connected to the first electrode CE1 of the remaining second sub-pixel SP2 of the pair of second sub-pixels SP2, for example, the second-second sub-pixel SP2b.

The fifth signal wiring TL5 can be disposed at one side of the pair of third sub-pixels SP3, and the sixth signal wiring TL6 can be disposed at the other side of the pair of third sub-pixels SP3. For example, the fifth signal wiring TL5 can be disposed neighboring the fourth signal wiring TL4. The sixth signal wiring TL6 can be disposed neighboring the first signal wiring TL1 connected to the neighboring pixel PX. The fifth signal wiring TL5 can be electrically connected to the first electrode CE1 of one of the third sub-pixels SP3 of the pair of third sub-pixels SP3, for example, the third-first sub-pixel SP3a. The sixth signal wiring TL6 can be electrically connected to the first electrode CE1 of the remaining third sub-pixel SP3 of the pair of third sub-pixels SP3, for example, the third-second sub-pixel SP3b.

The plurality of signal wirings TL can be configured with a conductive material. For example, the plurality of signal wirings TL can be configured with a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present disclosure are not limited thereto. As another example, the plurality of signal wirings TL can be formed of a multilayer structure of conductive material. For example, the plurality of signal wirings TL can be configured in a multilayer structure of titanium (Ti)/aluminum (Al)/titanium (Ti)/indium tin oxide (ITO), but the embodiments of the present disclosure are not limited thereto.

The plurality of communication wirings NL can be disposed in an area between the plurality of pixels PX. The plurality of communication lines NL can be disposed to extend in the row direction in the area between the plurality of pixels PX. The plurality of communication wirings NL can be disposed in an area between the plurality of second electrodes CE2s, and may not overlap with the plurality of second electrodes CE2s. For example, the plurality of communication wirings NL can be wirings used for short-range communication such as Near Field Communication (NFC). The plurality of communication wirings NL can function as antennas. For example, the plurality of communication wirings NL can be a plurality of connection wirings or the like, but the embodiments of the present disclosure are not limited thereto.

According to the present disclosure, the bank BNK can be disposed in each of the plurality of sub-pixels. A plurality of banks BNK can be structures on which a plurality of light-emitting elements ED are mounted. The plurality of banks BNK can guide the positions of the plurality of light-emitting elements ED in a transfer process during which the plurality of light-emitting elements ED are transferred to the display device 1000. In a transfer process of a plurality of light-emitting elements ED, a plurality of light-emitting elements ED can be transferred onto a plurality of banks BNK. The plurality of banks BNK can be bank patterns, bank layers or structures, but the embodiments of the present disclosure are not limited thereto.

The bank BNK of the first sub-pixel SP1, the bank BNK of the second sub-pixel SP2, and the bank BNK of the third sub-pixel SP3 can be disposed spaced apart from each other. The bank BNK of the first sub-pixel SP1, the bank BNK of the second sub-pixel SP2, and the bank BNK of the third sub-pixel SP3 can be configured to be separated from each other. Accordingly, the banks BNK of the first sub-pixel SP1, the second sub-pixel SP2, and the third sub-pixel SP3 to which different types of light-emitting elements ED are transferred can be easily identified.

The bank BNK of the first-first sub-pixel SP1a and the bank BNK of the first-second sub-pixel SP1b can be connected to each other, or can be formed to be spaced apart or separated from each other. For example, depending on the consideration of design requirements and the like of the transfer process, the bank BNK of the first-first sub-pixel SP1a and the bank BNK of the first-second sub-pixel SP1b in which the light-emitting elements ED of the same type are disposed can be connected to each other, or can be spaced apart or separated from each other. Further, the bank BNK of the second-first sub-pixel SP2a and the bank BNK of the second-second sub-pixel SP2b can be connected to each other, or can be formed to be spaced apart or separated from each other. The bank BNK of the third-first sub-pixel SP3a and the bank BNK of the third-second sub-pixel SP3b can be connected to each other, or can be formed to be spaced apart or separated from each other. Accordingly, the banks BNK of the pair of first sub-pixels SP1, the banks BNK of the pair of second sub-pixels SP2, and the banks BNK of the pair of third sub-pixels SP3 can be formed in various ways, and so the embodiments of the present disclosure are not limited thereto.

For example, the plurality of banks BNK can be configured with an organic insulating material. The plurality of banks BNK can be configured in a single-layer or multi-layer structure of organic insulating material. For example, the plurality of banks BNK can be configured with a photo resist, polyimide (PI), or acrylic-based material, or the like, but the embodiments of the present disclosure are not limited thereto.

The first electrode CE1 can be disposed on each of the plurality of sub-pixels. The first electrode CE1 can be disposed on the bank BNK. The first electrode CE1 can be electrically connected to one of the plurality of signal wirings TL. At least a portion of the first electrode CE1 can extend outside of the bank BNK to be electrically connected to a signal wiring TL closest to the first electrode CE1. For example, a portion of the first electrode CE1 of the first-first sub-pixel SP1a can extend to one side area of the first-first sub-pixel SP1a to be electrically connected to the first signal wiring TL1, and a portion of the first electrode CE1 of the first-second sub-pixel SP1b can extend to another side area of the first-second sub-pixel SP1b to be electrically connected to the second signal wiring TL2. A portion of the first electrode CE1 of the second-first sub-pixel SP2a can extend to one side area of the second-first sub-pixel SP2a to be electrically connected to the third signal wiring TL3, and a portion of the first electrode CE1 of the second-second sub-pixel SP2b can extend to another side area of the second-second sub-pixel SP2b to be electrically connected to the fourth signal wiring TL4. A portion of the first electrode CE1 of the third-first sub-pixel SP3a can extend to one side area of the third-first sub-pixel SP3a to be electrically connected to the fifth signal wiring TL5, and a portion of the first electrode CE1 of the third-second sub-pixel SP3b can extend to another side area of the third-second sub-pixel SP3b to be electrically connected to the sixth signal wiring TL6.

The first electrode CE1 can be electrically connected to the anode electrode 134 of the light-emitting element ED to transmit the anode voltage from the pixel driving circuit PD to the light-emitting element ED through the signal wiring TL. To the first electrode CE1 of each of the plurality of sub-pixels, a different voltage can be applied depending on the image to be displayed. For example, a different voltage can be applied to the first electrode CE1 of each of the plurality of sub-pixels. By this, the first electrode CE1 can be a pixel electrode, and the embodiments of the present disclosure are not limited thereto.

The first electrode CE1 can be configured with a conductive material. For example, the first electrode CE1 can be configured as one body with a plurality of signal wirings TL. For example, the first electrode CE1 can be configured with the same conductive material as the plurality of signal wirings TL, but the embodiments of the present disclosure are not limited thereto. For example, the first electrode CE1 can be configured with a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present disclosure are not limited thereto. As another example, the first electrode CE1 can be configured in a multilayer structure of conductive material. For example, the plurality of first electrode CE1 can be configured in a multilayer structure of titanium (Ti)/aluminum (Al)/titanium (Ti)/indium tin oxide (ITO), but the embodiments of the present disclosure are not limited thereto.

The light-emitting element ED can be disposed in each of the plurality of sub-pixels. The plurality of light-emitting elements ED can be disposed on the bank BNK and the first electrode CE1. The plurality of light-emitting elements ED can be disposed on the first electrode CE1 to be electrically connected to the first electrode CE1. Therefore, the light-emitting element ED can emit light by receiving an anode voltage from the pixel driving circuit PD through the signal wiring TL and the first electrode CE1.

The plurality of light-emitting elements ED can include a first light-emitting element 130, a second light-emitting element 140, and a third light-emitting element 150. The first light-emitting element 130 can be disposed in the first sub-pixel SP1. The second light-emitting element 140 can be disposed in the second sub-pixel SP2. The third light-emitting element 150 can be disposed in the third sub-pixel SP3. For example, one of the first light-emitting element 130, the second light-emitting element 140, and the third light-emitting element 150 can be a red light-emitting element, another thereof can be a green light-emitting element, and the remaining one thereof can be blue light-emitting elements, but the embodiments of the present disclosure are not limited thereto. Accordingly, by combining red light, green light, and blue light emitted from the plurality of light-emitting elements ED, light of various colors, including white, can be implemented. The types of the plurality of light-emitting elements ED are given only as an example, and the embodiments of the present disclosure are not limited thereto.

The first light-emitting element 130 can include a first-first light-emitting element 130a disposed in the first-first sub-pixel SP1a and a first-second light-emitting element 130b disposed in the first-second sub-pixel SP1b. The second light-emitting element 140 can include a second-first light-emitting element 140a disposed in the second-first sub-pixel SP2a and a second-second light-emitting element 140b disposed in the second-second sub-pixel SP2b. The third light-emitting element 150 can include a third-first light-emitting element 150a disposed in the third-first sub-pixel SP3a and a third-second light-emitting element 150b disposed in the third-second sub-pixel SP3b.

Referring to FIGS. 5, 6, 7, and 9 together, the second electrode CE2 can be disposed on each of the plurality of sub-pixels. The second electrode CE2 can be disposed on the light-emitting element ED. The second electrode CE2 can be electrically connected to the pixel driving circuit PD through a plurality of contact electrodes CCE.

For example, the second electrode CE2 can be electrically connected to the cathode electrode 135 of the light-emitting element ED to transmit the cathode voltage from the pixel driving circuit PD to the light-emitting element ED. The same cathode voltage can be applied to the second electrode CE2 of each of the plurality of sub-pixels. For example, the same voltage can be applied to the second electrode CE2 of each of the plurality of sub-pixels and the cathode electrode 135 of the light-emitting element ED. By this, the second electrode CE2 can be a common electrode, but the embodiments of the present disclosure are not limited thereto.

At least some of the plurality of sub-pixels can share the second electrode CE2 with each other. At least some of the second electrodes CE2 of the plurality of respective sub-pixels can be electrically connected to each other. As the same voltage is applied to the second electrodes CE2, the second electrode CE2 can be shared to be used for at least some sub-pixels. For example, the second electrodes CE2 of at least some of the pixels PX among the plurality of pixels PX disposed in the same row can be connected to each other. For example, one second electrode CE2 can be disposed on a plurality of pixels PX. One second electrode CE2 can be disposed for every n sub-pixels.

For example, some of the second electrodes CE2 of the plurality of respective sub-pixels can be disposed to be spaced apart from or separated from each other. For example, the second electrode CE2 connected to the pixels PX of the nth row and the second electrode CE2 connected to the pixels PX of the n+1th row can be disposed to be spaced apart from each other or separated from each other. For example, the plurality of second electrodes CE2 can be disposed to be spaced apart from each other with a plurality of communication wirings NL interposed and extending therebetween in the row direction. Thus, the number of the plurality of sub-pixels can be greater than the number of the plurality of second electrodes CE2. As another example, all of the second electrodes CE2 of a plurality of sub-pixels can be connected to each other so that only one second electrode CE2 is placed on the substrate 110, but the embodiments of the present disclosure are not limited thereto.

The plurality of second electrodes CE2 can be configured with a transparent conductive material, but the embodiments of the present disclosure are not limited thereto. The plurality of second electrodes CE2 can be configured with a transparent conductive material, so that light emitted from the light-emitting element ED can be directed toward the upper side of the second electrodes CE2. For example, the second electrode CE2 can be configured with a transparent conductive material such as indium tin oxide (ITO), indium zinc oxide (IZO), indium gallium zinc oxide (IGZO), or the like, but the embodiments of the present disclosure are not limited thereto.

The plurality of contact electrodes CCE can be disposed on the substrate 110. For example, the plurality of contact electrodes CCE can be disposed to be spaced apart from the plurality of banks BNK and the plurality of signal wirings TL. Each of the plurality of second electrodes CE2 can overlap with at least one contact electrode CCE. For example, one second electrode CE2 can overlap with the plurality of contact electrodes CCE.

For example, a plurality of contact electrodes CCE can be electrically connected to a plurality of second electrodes CE2. The plurality of contact electrodes CCE can be disposed between the substrate 110 and the plurality of second electrodes CE2 to transmit the cathode voltage from the pixel driving circuit PD to the second electrodes CE2.

For example, in a case where a micro LED is used as the light-emitting element ED, a plurality of micro LEDs can be formed on a wafer, and the micro LEDs can be transferred to the substrate 110 of the display device 1000 to manufacture the display device 1000. In the process of transferring a plurality of light-emitting elements ED having a microscopic size from the wafer to the substrate 110, various defects can be formed. For example, in some sub-pixels, a non-transfer defect can occur in which the light-emitting element ED is not transferred, and in other some sub-pixels, a defect can occur in which the light-emitting element ED is transferred outside the predetermined position due to an alignment error. Additionally, although the transfer process has been performed normally, the transferred light-emitting element ED itself can be defective. Therefore, taking into account the defects produced during the transfer process of the plurality of light-emitting elements ED, a plurality of light-emitting elements ED of the same type can be transferred to one sub-pixel. Lighting tests can be performed on the plurality of light-emitting elements ED, and only one light-emitting element ED that is ultimately determined to be normal can be used.

For example, the first-first light-emitting element 130a and the first-second light-emitting element 130b can be transferred together to one pixel PX, and can be tested to find whether they are defective or not. If both the first-first light-emitting element 130a and the first-second light-emitting element 130b are determined to be normal, only the first-first light-emitting element 130a can be used, and the first-second light-emitting element 130b may not be used. As another example, if only the first-second light-emitting element 130b among the first-first light-emitting element 130a and the first-second light-emitting element 130b is determined to be normal, the first-first light-emitting element 130a may not be used and only the first-second light-emitting element 130b can be used. Therefore, even if a plurality of light-emitting elements ED of the same type are transferred to one pixel PX, only one light-emitting element ED can be used ultimately.

Accordingly, one of the pair of light-emitting elements ED can be a main or primary light-emitting element ED, and the other light-emitting element ED thereof can be a redundant light-emitting element ED. The redundant light-emitting element ED can be a spare light-emitting element ED that has been transferred to prepare for failure of the main light-emitting element ED. In case of the failure of the main light-emitting element ED, the redundant light-emitting element ED can be used as a replacement for it. Therefore, by transferring the main light-emitting element ED and the redundant light-emitting element ED together to one pixel PX, the deterioration of display quality due to defects in the main light-emitting element ED and the redundant light-emitting element ED can be minimized.

For example, the first-first light-emitting element 130a, the second-first light-emitting element 140a, and the third-first light-emitting element 150a transferred to one pixel PX can be used as main light-emitting elements ED, while the first-second light-emitting element 130b, the second-second light-emitting element 140b, and the third-second light-emitting element 150b can be used as redundant light-emitting elements ED.

FIG. 8 is a cross-sectional view of a display device taken along line VIII-VIII′ in FIG. 3. FIG. 9 is a cross-sectional view of a display device according to an embodiment of the present disclosure. For example, FIG. 8 is a cross-sectional view of the display area AA, the first non-display area NA, the bending area BA, and the second non-display area NA2. For example, FIG. 9 is a cross-sectional view of a display area including one sub-pixel SP1. Meanwhile, for convenience of illustration, the line VIII-VIII′ in FIG. 3 is illustrated as not overlapping with the driving wiring VL and the link wiring LL, but the line VIII-VIII′ in FIG. 3 is intended to indicate the same position as the adjacent driving wiring VL and link wiring LL.

Referring to FIG. 8, in the remaining area of the substrate 110 except the bending area BA a first buffer layer 111a and a second buffer layer 111b can be disposed.

The first buffer layer 111a and the second buffer layer 111b can be disposed in the display area AA, the first non-display area NA1, and the second non-display area NA2. The first buffer layer 111a and the second buffer layer 111b can reduce the penetration of moisture or impurities through the substrate 110. The first buffer layer 111a and the second buffer layer 111b can be configured with an inorganic insulating material. For example, the first buffer layer 111a and the second buffer layer 111b can be configured in a single-layer or multi-layer structure of silicon oxide (SiOx) or silicon nitride (SiNx), but the embodiments of the present disclosure are not limited thereto.

For example, a portion of the first buffer layer 111a and the second buffer layer 111b on the bending area BA can be removed. The upper surface of the substrate 110 located in the bending area BA can be exposed from the first buffer layer 111a and the second buffer layer 111b. By removing the first buffer layer 111a and the second buffer layer 111b configured with an inorganic insulating material from the bending area BA, it is possible to minimize the cracks that can be produced in the first buffer layer 111a and the second buffer layer 111b when being bent.

Between the first buffer layer 111a and the second buffer layer 111b a plurality of alignment keys MK can be disposed. The plurality of alignment keys MK can be configured to identify the position of the pixel driving circuit PD during the manufacturing process of the display device 1000. For example, the plurality of alignment keys MK can be configured to align the position of the pixel driving circuit PD transferred on the adhesive layer 112. As another example, the plurality of alignment keys MK can be omitted.

On the second buffer layer 111b, the adhesive layer 112 can be disposed. The adhesive layer 112 can be disposed in the display area AA, the first non-display area NA1, the bending area BA, and the second non-display area NA2. As another example, at least a portion of the adhesive layer 112 can be removed from the non-display area NA including the bending area BA. For example, the adhesive layer 112 can be configured with any one of an adhesive polymer, an epoxy resin, a UV-curable resin, a polyimide series, an acrylate series, a urethane series, and polydimethylsiloxane (PDMS), but the embodiments of the present disclosure are not limited thereto.

On the adhesive layer 112 in the display area AA, the pixel driving circuit PD can be disposed. In a case where the pixel driving circuit PD is implemented with a driving driver, the driving driver can be mounted on the adhesive layer 112 by a transfer process, but the embodiments of the present disclosure are not limited thereto.

On the adhesive layer 112 and the pixel driving circuit PD, a first protective layer 113a and a second protective layer 113b can be disposed. The first protective layer 113a and the second protective layer 113b can be disposed to surround the side surface of the pixel driving circuit PD, but the embodiments of the present disclosure are not limited thereto. For example, the second protective layer 113b can be disposed to cover at least a portion of the upper surface of the pixel driving circuit PD. For example, at least one of the first protective layer 113a and the second protective layer 113b disposed on the bending area BA can be omitted. For example, the first protective layer 113a can be disposed entirely in the display area AA and the non-display area NA, and the second protective layer 113b can be disposed in part in the display area AA, the first non-display area NA1, and the second non-display area NA2. For example, a portion of the second protective layer 113b in the bending area BA can be removed. However, the embodiments of the present disclosure are not limited thereto.

The first protective layer 113a and the second protective layer 113b can be configured with an organic insulating material, but the embodiments of the present disclosure are not limited thereto. For example, the first protective layer 113a and the second protective layer 113b can be configured with a photo resist, polyimide (PI), or photo acryl-based material, or the like, but the embodiments of the present disclosure are not limited thereto. For example, the first protective layer 113a and the second protective layer 113b can be an overcoating layer or an insulating layer, but the embodiments of the present disclosure are not limited thereto.

According to the present disclosure, on the second protective layer 113b in the display area AA, a plurality of first connection wirings 121 can be disposed. The plurality of first connection wirings 121 can be wirings for electrically connecting the pixel driving circuit PD with another component. For example, a pixel driving circuit PD can be electrically connected to the plurality of signal wirings TL, the plurality of contact electrodes CCE and the like through the plurality of first connection wirings 121. For example, the plurality of first connection wirings 121 can include a first-first connection wiring 121a, a first-second connection wiring 121b, a first-third connection wiring 121c, and a first-fourth connection wiring 121d, but the embodiments of the present disclosure are not limited thereto.

For example, a plurality of first-first connection wirings 121a can be disposed on the second protective layer 113b. The plurality of first-first connection wirings 121a can be electrically connected to the pixel driving circuit PD. The plurality of first-first connection wirings 121a can transmit a voltage output from the pixel driving circuit PD to the first electrode CE1 or the second electrode CE2.

For example, on the second protective layer 113b, a third protective layer 114 can be disposed. The third protective layer 114 can be disposed entirely in the display area AA and the non-display area NA. In the bending area BA, the third protective layer 114 can cover or surround the side surface of the second protective layer 113b and the upper surface of the first protective layer 113a. The third protective layer 114 can be configured with an organic insulating material. For example, the third protective layer 114 can be configured with a photo resist, polyimide (PI), or photo acryl-based material, or the like, but the embodiments of the present disclosure are not limited thereto. For example, the first protective layer 113a, the second protective layer 113b, and the third protective layer 114 can be configured with the same material, but the embodiments of the present disclosure are not limited thereto.

On the third protective layer 114, a plurality of first-second connection wirings 121b can be disposed. The plurality of first-second connection wirings 121b can be connected to or directly connected to the pixel driving circuit PD. For example, a portion of the first-second connection wiring 121b can be directly connected to the pixel driving circuit PD through the contact hole in the third protective layer 114. Another portion of the first-second connection wiring 121b can be electrically connected to the first-first connection wiring 121a through the contact hole in the 3rd protective layer 114. However, the embodiments of the present disclosure are not limited thereto. The voltage output from the pixel driving circuit PD can be transmitted to the first electrode CE1 or the second electrode CE2 through the plurality of first-second connection wirings 121b and another connection wiring.

On the plurality of first-second connection wirings 121b, a first insulating layer 115a can be disposed. The first insulating layer 115a can be disposed entirely in the display area AA and the non-display area NA, but the embodiments of the present disclosure are not limited thereto. The first insulating layer 115a can be configured with an organic insulating material, but the embodiments of the present disclosure are not limited thereto. For example, the first insulating layer 115a can be configured with a photo resist, polyimide (PI), or photo acryl-based material, or the like, but the embodiments of the present disclosure are not limited thereto.

On the first insulating layer 115a, a plurality of first-third connection wirings 121c can be disposed. The plurality of first-third connection wirings 121c can be electrically connected to the plurality of first-second connection wirings 121b. For example, the first-third connection wiring 121c can be electrically connected to the first-second connection wiring 121b through the contact hole in the first insulating layer 115a.

On the plurality of first-third connection wirings 121c, a second insulating layer 115b can be disposed. The second insulating layer 115b can be disposed in the remaining area except the bending area BA, but the embodiments of the present disclosure are not limited thereto. The second insulating layer 115b can be disposed in the display area AA, the first non-display area NA1, and the second non-display area NA2, but the embodiments of the present disclosure are not limited thereto. For example, a portion of the second insulating layer 115b disposed in the bending area BA can be removed. The second insulating layer 115b can be configured with an organic insulating material, but the embodiments of the present disclosure are not limited thereto. For example, the second insulating layer 115b can be configured with a photo resist, polyimide (PI), or photo acryl-based material, or the like, but the embodiments of the present disclosure are not limited thereto.

On the second insulating layer 115b, a plurality of first-fourth connection wirings 121d can be disposed. The plurality of first-fourth connection wirings 121d can be electrically connected to the plurality of first-third connection wirings 121c. For example, the first-fourth connection wiring 121d can be electrically connected to the first-third connection wiring 121c through the contact hole in the second insulating layer 115b.

According to the present disclosure, on the second protective layer 113b in the non-display area NA, a plurality of second connection wirings 122 can be disposed. The plurality of second connection wirings 122 can be wirings for transmitting, to the pixel driving circuit PD in the display area AA, signals transmitted from the flexible circuit board (or flexible film) 157 and the printed circuit board 160 (see FIG. 1) to the pad part PAD. For example, the plurality of second connection wirings 122 can be electrically connected to the plurality of pad electrodes PE to receive signals from the flexible circuit board (or flexible film) 157 and the printed circuit board.

For example, the plurality of second connection wirings 122 can extend from the pad part PAD toward the display area AA to transmit signals to the wirings of the display area AA. In this case, the plurality of second connection wirings 122 can function as the link wirings LL. The plurality of second connection wirings 122 can include a second-first connection wiring 122a, a second-second connection wiring 122b, a second-third connection wiring 122c, and a second-fourth connection wiring 122d.

On the second protective layer 113b, a plurality of second-first connection wirings 122a can be disposed. The plurality of second-first connection wirings 122a can extend from the second non-display area NA2 to the bending area BA and the first non-display area NA1. The plurality of second-first connection wirings 122a can transmit, to the pixel driving circuit PD of the display area AA, signals transmitted from the flexible circuit board (or flexible film) 157 and the printed circuit board to the pad part PAD.

On the third protective layer 114, a plurality of second-second connection wirings 122b can be disposed. The plurality of second-second connection wirings 122b can be disposed in the second non-display area NA2. The second-second connection wiring 122b can be electrically connected to the second-first connection wiring 122a through the contact hole in the third protective layer 114. Accordingly, signals from the flexible circuit board (or flexible film) 157 and the printed circuit board can be transmitted to the second-first connection wiring 122a through the second-second connection wiring 122b.

On the first insulating layer 115a, the second-third connection wiring 122c can be disposed. The second-third connection wiring 122c can be disposed in the second non-display area NA2. The second-third connection wiring 122c can be electrically connected to the second-second connection wiring 122b through the contact hole in the first insulating layer 115a. Accordingly, signals from the flexible circuit board (or flexible film) 157 and the printed circuit board can be transmitted to the second-first connection wiring 122a through the second-third connection wiring 122c and the second-second connection wiring 122b.

On the second insulating layer 115b, the second-fourth connection wiring 122d can be disposed. The second-fourth connection wiring 122d can be disposed in the second non-display area NA2. The second-fourth connection wiring 122d can be electrically connected to the second-third connection wiring 122c through the contact hole in the second insulating layer 115b. Accordingly, signals from the flexible film (FF) and the printed circuit board can be transmitted to the second-first connection wiring 122a through the second-fourth connection wiring 122d, the second-third connection wiring 122c and the second-second connection wiring 122b.

The plurality of first connection wirings 121 and the plurality of second connection wirings 122 can be formed with any one of various conductive materials used in the display area AA or a conductive material having excellent ductility. For example, the second connection wiring whose portion is disposed in the bending area can be configured with a conductive material having excellent ductility, such as gold Au, silver Ag, aluminum Al or the like, but the embodiments of the present disclosure are not limited thereto. As another example, the plurality of first connection wiring 121 and the plurality of second connection wiring 122 can be configured with molybdenum (Mo), chromium (Cr), titanium (Ti), nickel (Ni), neodymium (Nd), copper (Cu), and an alloy of silver (Ag) and magnesium (Mg), or any alloy thereof, but the embodiments of the present disclosure are not limited thereto.

On a plurality of first connection wirings 121 and a plurality of second connection wirings 122, the third insulating layer 115c can be disposed. The third insulating layer 115c can be disposed in the remaining area except the bending area BA, but the embodiments of the present disclosure are not limited thereto. The third insulating layer 115c can be disposed in the display area AA, the first non-display area NA1, and the second non-display area NA2. A portion of the third insulating layer 115c in the bending area BA can be removed. The third insulating layer 115c can be configured with an organic insulating material, but the embodiments of the present disclosure are not limited thereto. For example, the third insulating layer 115c can be configured with a photo resist, polyimide (PI), or photo acryl-based material, or the like, but the embodiments of the present disclosure are not limited thereto.

On the third insulating layer 115c in the display area AA, a plurality of banks BNK can be disposed. The plurality of banks BNK can be disposed to overlap with each of the plurality of sub-pixels. On the upper side of each of the plurality of banks BNK one or more light-emitting elements ED of the same kind can be disposed.

On the third insulating layer 115c in the display area AA, a plurality of signal wirings TL can be disposed. The plurality of signal wirings TL can be disposed in the area between the plurality of banks BNK. For example, the plurality of signal wirings TL can be disposed adjacent to any one of the plurality of banks BNK.

On the third insulating layer 115c in the display area AA, a plurality of contact electrodes CCE can be disposed. The plurality of contact electrodes CCE can supply the cathode voltage from the pixel driving circuit PD to the second electrode CE2.

On the bank BNK the first electrode CE1 can be disposed. For example, the first electrode CE1 can be disposed to extend from the adjacent signal wiring TL toward the upper side of the bank BNK. The first electrode CE1 can be disposed on the upper surface of the bank BNK and on the side surface of the bank BNK. For example, the first electrode CE1 can be disposed to extend from the signal wiring TL on the upper surface of the third insulating layer 115c to the side surface of the bank BNK and the upper surface of the bank BNK.

Referring to FIG. 9, the first electrode CE1 can be configured with a plurality of conductive layers. For example, the first electrode CE1 can include a first conductive layer CE1a, a second conductive layer CE1b, a third conductive layer CE1c, and a fourth conductive layer CE1d, but the embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, each of the first conductive layer CE1a, the second conductive layer CE1b, the third conductive layer CE1c, and the fourth conductive layer CE1d can be configured with titanium (Ti), molybdenum (Mo), aluminum (Al), or titanium (Ti) and indium tin oxide (ITO), but the embodiments of the present disclosure are not limited thereto.

According to the present disclosure, among the plurality of conductive layers constituting the first electrode CE1, some of the conductive layers having good reflection efficiency can be configured as alignment keys and/or reflecting plates for aligning the light-emitting element ED. For example, among the plurality of conductive layers of the first electrode CE1, the second conductive layer CE1b can include a reflective material. For example, the second conductive layer CE1b can include aluminum (Al), but embodiments of the present disclosure are not limited thereto. Accordingly, the second conductive layer CE1b can constitute the reflecting plate. In addition, due to the high reflection efficiency of the second conductive layer CE1b, it can be easily identified during the manufacturing process, and thus the position or transfer position of the light-emitting element ED can be aligned based on the second conductive layer CE1b.

For example, in order to form the second conductive layer CE1b as the reflecting plate, the third conductive layer CE1c and the fourth conductive layer CE1d covering the second conductive layer CE1b can be partially removed or etched. For example, a portion of the third conductive layer CE1c and the fourth conductive layer CE1d disposed on the bank BNK can be removed or etched to expose the upper surface of the second conductive layer CE1b. For example, the central portion and the border portion or edge portion of the third conductive layer CE1c and the fourth conductive layer CE1d can be left, and the remaining portion can be removed, wherein the solder pattern SDP is placed on the central portion. For example, the border portion or edge portion of each of the third conductive layer CE1c configured with titanium (Ti) and the fourth conductive layer CE1d configured with indium tin oxide (ITO) may not be etched. Accordingly, it is possible to prevent other conductive layers of the first electrode CE1 from being corroded by the TMAH (TetraMethylAmmoniumHydroxide) solution used in the mask process of the first electrode CE1.

According to the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide ITO or indium zinc oxide IZO, which has good adhesion to the solder pattern SDP and has corrosion resistance and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process, but the embodiments of the present disclosure are not limited thereto.

According to the present disclosure, the signal wiring TL, the contact electrode CCE, and the pad electrode PE disposed on the same layer as the first electrode CE1 can be configured in a multi-layer structure of conductive materials, but the embodiments of the present disclosure are not limited thereto. For example, the signal wiring TL, contact electrode CCE, and pad electrode PE can be formed in a multi-layer structure of indium tin oxide (ITO)/titanium (Ti)/aluminum (Al)/titanium (Ti), but the embodiments of the present disclosure are not limited thereto.

According to the present disclosure, the solder pattern SDP can be disposed on the first electrode CE1 in each of the plurality of sub-pixels. The solder pattern SDP can electrically connect the first electrode CE1 with the light-emitting element ED by bonding the light-emitting element ED to the first electrode CE1. The first electrode CE1 and the anode electrode 134 of the light-emitting element ED can be electrically connected through eutectic bonding using the solder pattern SDP, but the embodiments of the present disclosure are not limited thereto. For example, in a case where the solder pattern SDP is configured with indium (In) and the anode electrode (134) of the light-emitting element ED is configured with gold (Au), the solder pattern SDP and the anode electrode 134 can be joined by applying heat and pressure during the transfer process of the light-emitting element ED. Through the eutectic bonding, the light-emitting element ED can be bonded to the solder pattern SDP and the first electrode CE1 without a separate adhesive material. For example, the solder pattern SDP can be configured with indium (In), tin (Sn) or alloys thereof, but embodiments of the present disclosure are not limited thereto. For example, the solder pattern SDP can be a bonding pad or a joining pad, but the embodiments of the present disclosure are not limited thereto.

According to the present disclosure, on the plurality of signal wirings TL, the plurality of first electrodes CE1, the plurality of contact electrodes CCE, and the third insulating layer 115c, a passivation layer 116 can be disposed. For example, the passivation layer 116 can be disposed in the display area AA, the first non-display area NA1, and the second non-display area NA2. A portion of the passivation layer 116 disposed in the bending area BA can be removed. A portion of the passivation layer 116 covering the plurality of pad electrodes PE in the second non-display area NA2 can be removed. The passivation layer 116 can be disposed to cover the remaining area except the bending area BA, the plurality of pad electrodes PE, and the area where the solder pattern SDP is disposed, thus capable of reducing the penetration of moisture or impurities into the light-emitting element ED. For example, the passivation layer 116 can be configured in a single-layer or multi-layer structure of silicon oxide (SiOx) or silicon nitride (SiNx), but the embodiments of the present disclosure are not limited thereto. For example, the passivation layer 116 can be a protective layer or an insulating layer, but the embodiments of the present disclosure are not limited thereto. For example, the passivation layer 116 can include a hole through which the solder pattern SDP is exposed.

In each of the plurality of sub-pixels, the light-emitting element ED can be disposed on the solder pattern SDP. In the first sub-pixel SP1 the first light-emitting element 130 can be disposed. In the second sub-pixel SP2 the second light-emitting element 140 can be disposed. In the third sub-pixel SP3 the third light-emitting element 150 can be disposed.

The light-emitting element ED can be formed on a silicon wafer by a method such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), Hydride Vapor Phase Epitaxy (HVPE), sputtering, or the like, but the embodiments of the present disclosure are not limited thereto.

Referring to FIG. 9, the first light-emitting element 130 can include the anode electrode 134, a first semiconductor layer 131, an active layer 132, a second semiconductor layer 133, a cathode electrode 135, and a scaling film 136, but the embodiments of the present disclosure are not limited thereto. For example, the first light-emitting element 130 may not include the scaling film 136.

On a solder pattern SDP the first semiconductor layer 131 can be disposed. On the first semiconductor layer 131, the second semiconductor layer 133 can be disposed.

For example, one of the first semiconductor layer 131 and the second semiconductor layer 133 can be implemented as a compound semiconductor of group III-V, group II-VI, or the like, and can be doped with an impurity or dopant. For example, one of the first semiconductor layer 131 and the second semiconductor layer 133 can be a semiconductor layer doped with an n-type impurity, and the other thereof can be a semiconductor layer doped with a p-type impurity, but the embodiments of the present disclosure are not limited thereto. For example, one of the first semiconductor layer 131 and the second semiconductor layer 133 can be a layer where an n-type or p-type impurity is doped in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity can be silicon (Si), germanium (Ge), selenium (Sc), carbon (C), tellurium (Te), tin (Sn), or the like, but the embodiments of the present disclosure are not limited thereto. For example, the p-type impurity can be magnesium (Mg), zinc (Zn), calcium (Ca), strontium (Sr), barium (Ba), beryllium (Be), or the like, but the embodiments of the present disclosure are not limited thereto.

For example, the first semiconductor layer 131 and the second semiconductor layer 133 can be a nitride semiconductor containing an n-type impurity and a nitride semiconductor containing a p-type impurity, respectively, but the embodiments of the present disclosure are not limited thereto. For example, the first semiconductor layer 131 can be a nitride semiconductor containing a p-type impurity, and the second semiconductor layer 133 can be a nitride semiconductor containing an n-type impurity, but the embodiments of the present disclosure are not limited thereto.

The active layer 132 can be disposed between the first semiconductor layer 131 and the second semiconductor layer 133. The active layer 132 can emit light by receiving holes and electrons from the first semiconductor layer 131 and the second semiconductor layer 133. For example, the active layer 132 can be configured in one of a single well structure, a multi-well structure, a single quantum well structure, a multi-quantum well (MQW) structure, a quantum dot structure, and a quantum wiring structure, but the embodiments of the present disclosure are not limited thereto. For example, the active layer 132 can be composed of indium gallium nitride (InGaN) or gallium nitride (GaN), but the embodiments of the present disclosure are not limited thereto.

As another example, the active layer 132 can include a multi-quantum well (MQW) structure having a well layer and a barrier layer having a higher band gap than the well layer. For example, the active layer 132 can be composed of InGaN as a well layer and an AlGaN layer as a barrier layer, but the embodiments of the present disclosure are not limited thereto.

The anode electrode 134 can be disposed between the first semiconductor layer 131 and the solder pattern SDP. For example, the anode electrode 134 can electrically connect the first semiconductor layer 131 with the first electrode CE1. The anode voltage output from the pixel driving circuit PD can be applied to the first semiconductor layer 131 through the signal wiring TL, the first electrode CE1, and the anode electrode 134. For example, the anode electrode 134 can be composed of a conductive material capable of eutectic bonding with the solder pattern SDP, but the embodiments of the present disclosure are not limited thereto. For example, the anode electrode 134 can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or any alloy thereof, but the embodiments of the present disclosure are not limited thereto.

The cathode electrode 135 can be disposed on the second semiconductor layer 133. For example, the cathode electrode 135 can electrically connect the second semiconductor layer 133 with the second electrode CE2. The cathode voltage output from the pixel driving circuit PD can be applied to the second semiconductor layer 133 through the contact electrode CCE, the second electrode CE2, and the cathode electrode 135. The cathode electrode 135 can be composed of a transparent conductive material so that light emitted from the light-emitting element ED can be directed to the upper side of the light-emitting element ED, but the embodiments of the present disclosure are not limited thereto. For example, the cathode electrode 135 can be configured with a material such as indium tin oxide (ITO), indium zinc oxide (IZO), indium gallium zinc oxide (IGZO), or the like, but the embodiments of the present disclosure are not limited thereto.

The scaling film 136 can be disposed on at least a portion of the first semiconductor layer 131, the active layer 132, the second semiconductor layer 133, the anode electrode 134, and the cathode electrode 135. For example, the sealing film 136 can surround at least a portion of the first semiconductor layer 131, the active layer 132, the second semiconductor layer 133, the anode electrode 134, and the cathode electrode 135.

For example, the sealing film 136 can protect the first semiconductor layer 131, the active layer 132, and the second semiconductor layer 133. For example, the sealing film 136 can be disposed on the side surface of the first semiconductor layer 131, the side surface of the active layer 132, and the side surface of the second semiconductor layer 133.

For example, the sealing film 136 can be disposed on at least a portion of the anode electrode 134 and the cathode electrode 135, for example, an edge portion or a border portion or one side of the anode electrode 134 and an edge portion or a border portion or one side of the cathode electrode 135. At least a portion of the anode electrode 134 can be exposed from the sealing film 136 so that the anode electrode 134 and the solder pattern SDP can be connected to each other. For example, at least a portion of the cathode electrode 135 can be exposed from the sealing film 136 so that the cathode electrode 135 and the second electrode CE2 can be connected to each other. For example, the sealing film 136 can be configured with an insulating material such as silicon nitride (SiNx) or silicon oxide (SiOx), but the embodiments of the present disclosure are not limited thereto.

As another example, the sealing film 136 can be configured as a resin layer in which a reflective material is dispersed, but the embodiments of the present disclosure are not limited thereto. For example, the sealing film 136 can be manufactured as a reflector having various structures, but the embodiments of the present disclosure are not limited thereto. Light emitted from the active layer 132 can be reflected to the upper side by the sealing film 136, so that light extraction efficiency can be improved. For example, the sealing film 136 can be a reflective layer, but the embodiments of the present disclosure are not limited thereto.

According to the present disclosure, the light-emitting element ED is described as having a vertical structure, but the embodiments of the present disclosure are not limited thereto. For example, the light-emitting element ED can have a lateral structure or a flip chip structure.

Although the first light-emitting element 130 has been described with reference to FIG. 9, the second light-emitting element 140 and the third light-emitting element 150 can have structures substantially identical to that of the first light-emitting element 130. For example, the second light-emitting element 140 and the third light-emitting element 150 can be substantially identical to the first semiconductor layer 131, the active layer 132, the second semiconductor layer 133, the anode electrode 134, the cathode electrode 135, and the sealing film 136 of the first light-emitting element 130.

According to the present disclosure, in the display area AA, there can be disposed a first optical layer 117a surrounding a plurality of light-emitting elements ED. For example, the first optical layer 117a can be disposed to cover a plurality of light-emitting elements ED and banks BNK in the areas of a plurality of sub-pixels. For example, the first optical layer 117a can cover the bank BNK, a portion of the passivation layer 116, and a gap between a plurality of light-emitting elements ED. The first optical layer 117a can cover or be disposed between a plurality of light-emitting elements ED and between a plurality of banks BNK included in one pixel PX. For example, the first optical layers 117a can extend in a first direction (X) and be spaced apart from each other in the second direction (Y). For example, the first optical layer 117a can be disposed to surround the side portion of the bank BNK and the light-emitting element ED between the passivation layer 116 and the second electrode CE2, but the embodiments of the present disclosure are not limited thereto. For example, the first optical layer 117a can be a first optical insulating layer, diffusion layer, or sidewall diffusion layer, but the embodiments of the present disclosure are not limited thereto.

The first optical layer 117a can include an organic insulating material having fine particles dispersed therein, but the embodiments of the present disclosure are not limited thereto. An explanation of this will be given later in FIG. 19.

For example, the first optical layer 117a can be disposed in each of the plurality of pixels PX, or can be disposed commonly for some of the pixels PX disposed in the same row, but the embodiments of the present disclosure are not limited thereto. For example, the first optical layer 117a can be disposed in each of a plurality of pixels PX, or a plurality of pixels PX can share one first optical layer 117a. As another example, each of the plurality of sub-pixels can separately include a first optical layer 117a, but the embodiments of the present disclosure are not limited thereto.

According to the present disclosure, on the passivation layer 116 in the display area AA, a second optical layer 117b can be disposed. For example, the second optical layer 117b can be disposed to surround the first optical layer 117a. For example, the second optical layer 117b can be in contact with a side surface of the first optical layer 117a. For example, the second optical layer 117b can be disposed in an area between a plurality of pixels PX. However, the embodiments of the present disclosure are not limited thereto. For example, the second optical layer 117b can be a second optical insulating layer, diffusion layer, diffusion layer window, or window diffusion layer, but the embodiments of the present disclosure are not limited thereto.

The second optical layer 117b can be composed of an organic insulating material, but the embodiments of the present disclosure are not limited thereto. The second optical layer 117b can be composed of the same material as the first optical layer 117a, but the embodiments of the present disclosure are not limited thereto. An explanation of this will be given later in FIG. 19.

According to the present disclosure, the second electrode CE2 can be disposed on the first optical layer 117a and the second optical layer 117b. For example, the second electrode CE2 can be electrically connected to the plurality of contact electrodes CCE through contact holes in the second optical layer 117b. For example, the second electrode CE2 can be disposed on a plurality of light-emitting elements ED. For example, the second electrode CE2 can include a transparent conductive oxide such as indium tin oxide (ITO) or indium zinc oxide (IZO), but the embodiments of the present disclosure are not limited thereto. For example, the second electrode CE2 can be disposed in contact with the cathode electrode 135. For example, the second electrode CE2 can overlap with the first optical layer 117a. For example, it can cover the outer plane of the first optical layer 117a.

The second electrode CE2 can extend continuously in the first direction of the substrate 110. Accordingly, it can be commonly connected to a plurality of pixels PX arranged in the first direction of the substrate 110. For example, the second electrode CE2 can be commonly connected to a plurality of pixels PX.

According to the present disclosure, the second electrode CE2 can extend continuously over the first optical layer 117a, the second optical layer 117b, and the light-emitting element ED. The area where the first optical layer 117a is disposed can include a concave portion that is recessed inward more than the upper surface of the second optical layer 117b. Accordingly, a first portion of the second electrode CE2 disposed on the first optical layer 117a is disposed along the concave portion, and thus can be disposed at a lower position than a second portion of the second electrode CE2 disposed on the second optical layer 117b.

On the second electrode CE2, a third optical layer 117c can be disposed. The third optical layer 117c can be disposed to overlap with the plurality of light-emitting elements ED and the first optical layer 117a. Since the third optical layer 117c is disposed on the second electrode CE2 and the plurality of light-emitting elements ED, it is possible to alleviate stains Mura that can occur on some of the plurality of light-emitting elements ED. For example, when transferring the plurality of light-emitting elements ED onto the substrate 110 of the display device 1000, its process deviation or the like can cause the occurrence of an area where the spacings between the plurality of light-emitting elements ED are not uniform. If the spacings between the plurality of light-emitting elements ED are uneven, the emission areas of the plurality of respective light-emitting elements ED can be disposed unevenly, which may, in turn, cause stains Mura to be visible to the user. To address this, the third optical layer 117c is constructed over the plurality of light-emitting elements ED so as to be configured to uniformly diffuse light over, and thus it is possible to alleviate the phenomenon in which light emitted from some light-emitting elements ED looks like stains. Accordingly, since the light emitted from the plurality of light-emitting elements ED is evenly diffused by the third optical layer 117c and extracted to the outside of the display device 1000, the brightness uniformity of the display device 1000 can be improved.

The third optical layer 117c can be composed of an organic insulating material having fine particles dispersed therein, but the embodiments of the present disclosure are not limited thereto. For example, the third optical layer 117c can be composed of siloxane having fine particles such as titanium dioxide (TiO₂) particles dispersed therein, but the embodiments of the present disclosure are not limited thereto. For example, the third optical layer 117c can be composed of the same material as the first optical layer 117a, but the embodiments of the present disclosure are not limited thereto. For example, the third optical layer 117c can be a diffusion layer or an upper surface diffusion layer, but the embodiments of the present disclosure are not limited thereto.

According to the present disclosure, light from a plurality of light-emitting elements ED can be emitted to the outside of the display device 1000 in a state of being scattered by fine particles dispersed in the third optical layer 117c. The third optical layer 117c can evenly mix the lights emitted from the plurality of light-emitting elements ED to further improve the brightness uniformity of the display device 1000. Furthermore, the light extraction efficiency of the display device 1000 can be improved by the light being scattered by the plurality of fine particles, thereby enabling the display device 1000 to be driven at low power.

On the second electrode CE2, the first optical layer 117a, the second optical layer 117b, and the third optical layer 117c in the display area AA, there can be disposed a black matrix BM. For example, the black matrix BM can fill the contact hole in the second optical layer 117b. The black matrix BM can be formed to cover the display area AA, so that color mixing of light from a plurality of sub-pixels and external light reflection can be reduced. For example, since the black matrix BM can also be disposed within the contact hole where the second electrode CE2 and the contact electrode CCE are connected to each other, light leakage between multiple neighboring sub-pixels can be prevented.

For example, the black matrix BM can be composed of an opaque material, but the embodiments of the present disclosure are not limited thereto. For example, the black matrix BM can be an organic insulating material having black pigment or black dye added thereto, but the embodiments of the present disclosure are not limited thereto.

On the black matrix BM in the display area AA, a cover layer 118 can be disposed. The cover layer 118 can protect the configuration under the cover layer 118. For example, the cover layer 118 can be composed of an organic insulating material, but the embodiments of the present disclosure are not limited thereto. For example, the cover layer 118 can be configured with a photo resist, polyimide (PI), or photo acryl-based material, or the like, but the embodiments of the present disclosure are not limited thereto. For example, the cover layer 118 can be an overcoating layer or an insulating layer, but the embodiments of the present disclosure are not limited thereto.

On the cover layer 118, the polarizing layer 293 can be disposed via a first adhesive layer 291. On the polarizing layer 293, the cover member 155 can be disposed via a second adhesive layer 295. For example, the first adhesive layer 291 and the second adhesive layer 295 can include an optically clear adhesive (OCA), an optically clear resin (OCR), or a pressure sensitive adhesive (PSA), but the embodiments of the present disclosure are not limited thereto.

According to the present disclosure, on the third insulating layer 115c in the second non-display area NA2, the plurality of pad electrodes PE can be disposed. For example, at least a portion of the plurality of pad electrodes PE can be exposed from the passivation layer 116. For example, a plurality of pad electrodes PE can be electrically connected to the second-fourth connection wiring 122d through the contact hole in the third insulating layer 115c.

On the plurality of pad electrodes PE, an adhesive layer ACF can be disposed. The adhesive layer ACF can be an adhesive layer in which conductive balls are dispersed in an insulating material, but the embodiments of the present disclosure are not limited thereto. In a case where heat or pressure is applied to the adhesive layer ACF, the conductive balls can be electrically connected in the part where the heat or pressure is applied, thereby providing conductive property. By placing the adhesive layer ACF between a plurality of pad electrodes PE and the flexible circuit board (or flexible film) 157, the flexible circuit board (or flexible film) 157 can be attached or bonded to a plurality of pad electrodes PE. For example, the adhesive layer ACF can be an anisotropic conductive film ACF, but the embodiments of the present disclosure are not limited thereto.

On the adhesive layer ACF, the flexible circuit board (or flexible film) 157 can be disposed. The flexible circuit board (or flexible film) 157 can be electrically connected to the plurality of pad electrodes PE through the adhesive layer ACF. Accordingly, signals output from the flexible circuit board (or flexible film) 157 and the printed circuit board can be transmitted to the pixel driving circuit PD in the display area AA through the plurality of pad electrodes PE, the second-fourth connection wiring 122d, the second-third connection wiring 122c, the second-second connection wiring 122b, and the second-first connection wiring 122a.

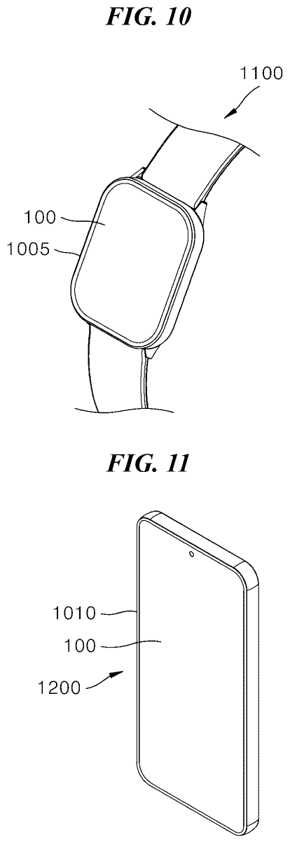

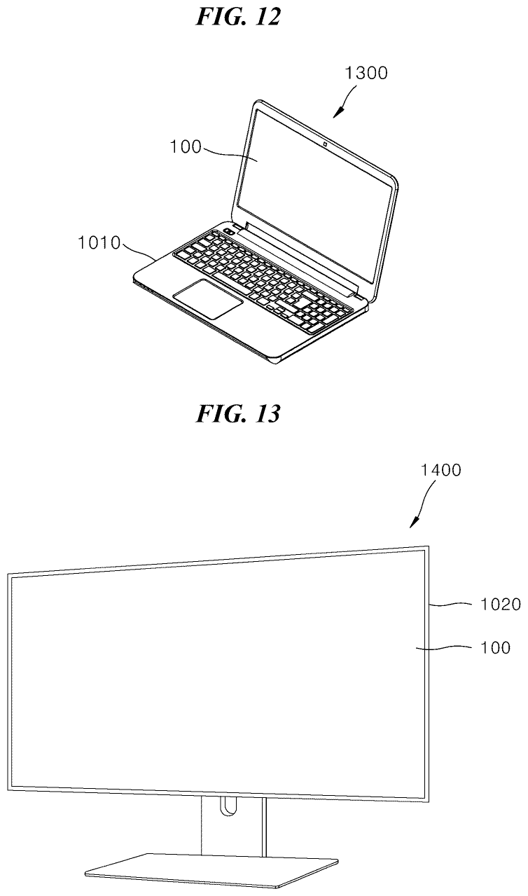

FIGS. 10 to 13 are views illustrating devices to which display devices according to embodiments of the present disclosure are applied.

Referring to FIGS. 10 to 13, the display device 1000 according to the embodiments of the present disclosure can be included in various devices or electronic devices. For example, referring to FIGS. 10 to 13, various electronic devices can include a wearable device 1100, a mobile device 1200, a notebook 1300, and a monitor or TV 1400, but the embodiments of the present disclosure are not limited thereto.

Each of the wearable device 1100, the mobile device 1200, the notebook 1300, and the monitor or TV 1400 can include a case 1005, 1010, 1015, 1020, the display panel 100 and the display device 1000 according to the embodiment of the present disclosure described with reference to FIGS. 1 to 9.

For example, the display device according to the embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, home appliances, or the like.

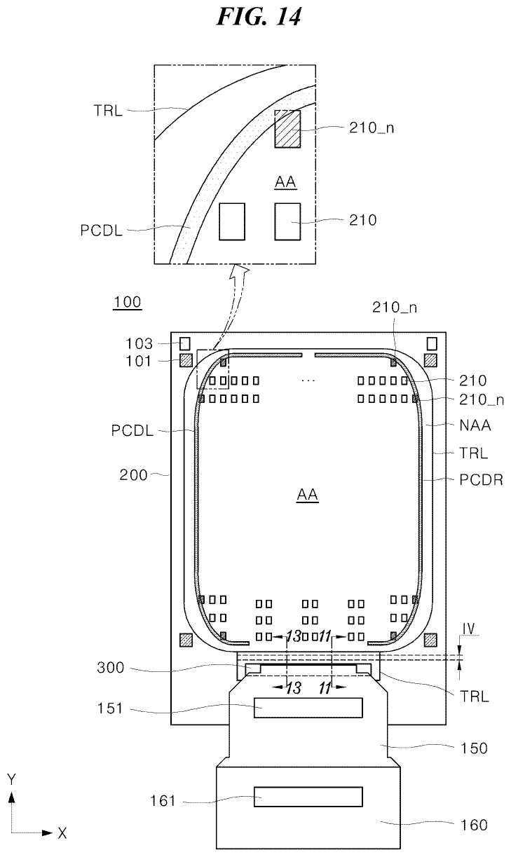

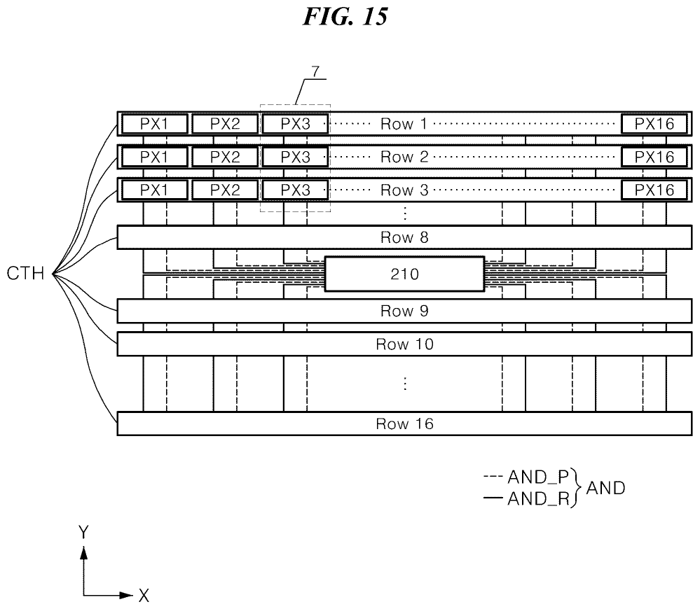

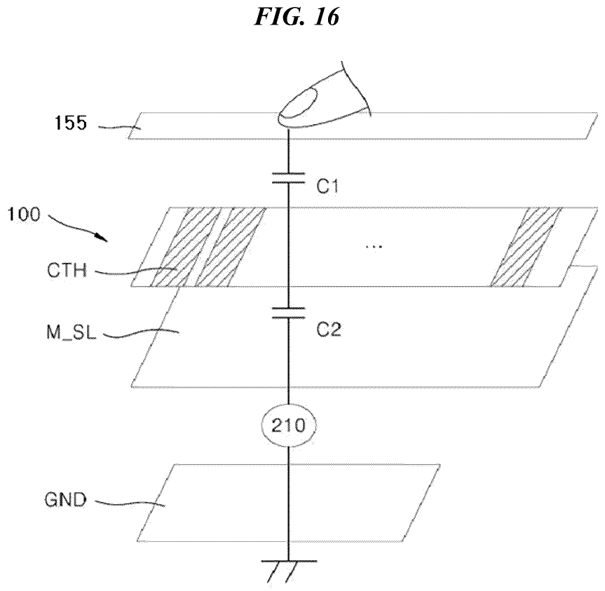

FIG. 14 is a plan view of a display device according to another embodiment of the present disclosure. FIG. 15 is a plan view showing an area where one of the plurality of pixel driving circuits of FIG. 14 is disposed. FIG. 16 is a drawing showing touch operation of a display device according to another embodiment of the present disclosure.

Referring to FIGS. 14 and 15, the display area AA of the display device 1000 according to another embodiment of the present disclosure can include a plurality of driving chips 210 as pixel driving circuits, and a plurality of pixels PX1, PX2, PX3 . . . PX16 including a plurality of light-emitting elements electrically connected to the driving chips 210. Each driving chip 210 can control the light-emitting operation of a plurality of light-emitting elements by supplying control signals and powers to a plurality of light-emitting elements.

The substrate 200 can have a shape in which one side is longer than another side. For example, the substrate 200 can include a long side having a longer length than the other side, and a short side having a shorter length than the long side. The short side can be disposed in the first direction X of the substrate 200, and the long side can be disposed in the second direction Y of the substrate 200; however, this is not exhaustive.

One or more crack detection lines PCDL, PCDR can be disposed in some areas of the non-display area NAA. Each of one or more crack detection wirings PCDL, PCDR can be disposed along the outer part of the display area AA to detect defects such as cracks that can occur in the outer part of the display area AA. One or more crack detection lines PCDL, PCDR can be disposed to surround at least a portion of both side areas, upper and lower areas of the display area AA. For example, the one or more crack detection lines PCDL, PCDR can include a first crack detection line PCDL and a second crack detection line PCDR.

The first crack detection line PCDL can be disposed along the left long side of the substrate 200, spanning between the upper side corner and the lower side corner, with the both ends extending in the upper and lower short side directions, respectively. The second crack detection line PCDR can be disposed along the right long side, facing opposite to the first crack detection line PCDL and spanning between the upper side corner and the lower side corner, with the both ends extending in the upper and lower short side directions, respectively. The first crack detection line PCDL and the second crack detection line PCDR can be disposed spaced apart from each other.

The first crack detection line PCDL and the second crack detection line PCDR can be disposed to overlap with some driving chips of the plurality of driving chips 210 at the corner. The driving chip disposed to overlap with the first and second crack detection lines PCDL, PCDR at the corner can be an inactive driving chip 210_n.

The inactive driving chip 210_n may not be electrically connected to at least some of the power wirings or the signal wirings as it is disposed to overlap with the first crack detection line PCDL or the second crack detection line PCDR at the corner of the substrate 200. Accordingly, the inactive driving chip 210_n can be a non-use driving chip that cannot control the plurality of light-emitting elements. The inactive driving chips 210_n can include at least eight driving chips of the plurality of driving chips 210, which are disposed in the outermost areas along the corners of the substrate 200.

The substrate 200 can include a trimming line TRL outside the non-display area NAA. The trimming line TRL can refer to a cutting area cut by a laser during a scribing process to separate a plurality of individual unit display panels 100 see FIG. 1 from the substrate 200. The outer side of the trimming line TRL can be removed through the scribing process.

In the outer side of the trimming line TRL a plurality of alignment key patterns 101, 103 can be disposed. The plurality of alignment key patterns 101, 103 can include, but are not limited to, a first sort key pattern 101 and a second sort key pattern 103. Since the plurality of alignment key patterns 101, 103 are disposed outside the trimming line TRL, they can be removed during the scribing process.

The first alignment key pattern 101 can be a pattern for alignment between the display panel 100 and the cover member 155 of FIG. 1. A plurality of first alignment key patterns 101 can be disposed with at least one at the outer side area of the trimming line TRL facing each corner of the substrate 200. For example, the plurality of first alignment key patterns 101 can be comprised of four alignment key patterns, each being disposed at a respective one of four corners of the substrate 200.

The second alignment key pattern 103 can include various alignment key patterns for aligning components disposed in different layers, such as a plurality of signal wirings, contact holes, and a plurality of driving drivers disposed on the substrate 200, to the correct positions. The second alignment key pattern 103 can include a metal material. Accordingly, the second alignment key pattern 103 can be disposed in the display area AA or the non-display area NAA, and be formed together with a plurality of signal wirings including a metal material, which, however, is given only as an example.

The plurality of driving chips 210, which are pixel driving circuits, can be arranged on the display area AA of the substrate 200. For example, the plurality of driving chips 210 can be arranged in a matrix shape; however, this is not exhaustive.

On a plurality of driving chips 210, a plurality of pixels including a plurality of light-emitting elements can be arranged in a matrix shape. The plurality of pixels can be arranged to be spaced apart from each other in a first direction and a second direction intersecting the first direction. The first direction can be the X-axis direction of the display panel 100, and the second direction can be the Y-axis direction of the substrate 200; however, this is not exhaustive. For example, the first direction can be the horizontal direction or row direction of the substrate 200, and the second direction can be the vertical direction or column direction of the substrate 200.

Each of the plurality of pixels can have sub-pixels that emit different colors disposed alternately in the first direction of the substrate 200. Additionally, sub-pixels emitting the same color can be disposed in the second direction of the substrate 200. For example, the first pixel PX1 to the sixteenth pixel PX16 can be arranged in the row direction, which is the first direction. A single pixel PX can include red R, green G, and blue B sub-pixels.

A plurality of light-emitting elements can be disposed corresponding to each sub-pixel. At least one light-emitting element can be disposed in one sub-pixel. For example, two light-emitting elements can be disposed in one sub-pixel. One of the two light-emitting elements can be a main light-emitting element and the other thereof can be a redundant light-emitting element. The light-emitting element can be a micro LED μLED. Accordingly, in the first direction, which is the row direction, the sub-pixels of red R, green G, and blue B can be disposed in a repeating order.

Additionally, sub-pixels emitting the same color can be disposed in the second direction, for example, the column direction. For example, sub-pixels of one color among red R, green G, or blue B can be disposed in the second direction, for example, the column direction. The sub-pixels emitting the same color can be electrically connected to each other via one first electrode AND_P, AND_R.

The first electrode AND can include a first line AND_P and a second line AND_R. The first line AND_P and the second line AND_R can be disposed to be spaced apart from each other in the first direction of the substrate 200. The first line AND_P of the first electrode AND can be connected to the main light-emitting element, and the second line AND_R of the first electrode AND can be connected to the redundant light-emitting element.

Each of the plurality of second electrodes CTH can extend in the first direction. Additionally, each of the plurality of second electrodes CTH can be arranged to be spaced apart from each other in the second direction. Accordingly, each second electrode CTH can extend in the first direction to be connected to each of the first to sixteenth pixels PX1 to PX16 disposed in each of a plurality of rows Row 1, Row2, Row 3, . . . , Row 16.

Each of the plurality of driving chips 210 includes a plurality of driving circuits, and drive a plurality of light-emitting elements. A single driving chip 210 can be connected to a plurality of first electrodes AND and second electrodes CTH connected to a plurality of pixels PX1, PX2, . . . , PX16. For example, one driving chip 210 can drive a plurality of light-emitting elements arranged on the first row Row1 to sixteenth row Row 16. In other words, one driving chip 210 can be electrically connected to a plurality of light-emitting elements arranged on the first row Row1 to the sixteenth row Row16 via the first electrode AND and the second electrode CTH, and can control the light-emitting operation of the plurality of light-emitting elements by supplying control signals and powers via the first electrode AND and the second electrode CTH.

A plurality of first electrodes AND connected to at least one driving chip 210 can be radially connected to connect a first pixel PX1 disposed at a first position in a first row Row1 and a sixteenth pixel PX16 disposed at a sixteenth position opposite to the first pixel PX1 to the driving chip 210, respectively. For example, the first row Row1 to the eighth row Row8 can be commonly connected to one first electrode AND, and the ninth row Row9 to the sixteenth row Row 16 can be commonly connected to a first electrode AND different from the first electrode AND to which the first row Row1 to the eighth row Row8 are connected. For example, the shape in which the plurality of first electrodes AND are connected can be a rhombus shape or an ‘I’ shape when viewed from a plane view.

The display device according to an embodiment of the present disclosure can have an in-cell touch structure that uses each of a plurality of second electrodes CTH as a touch electrode instead of forming separate touch electrodes. Accordingly, the thickness of the display panel can be reduced since separate touch electrodes are not formed.

Referring to FIG. 16, when a user's touch operation is performed on the cover member 155, a change in a first capacitance C1 between the plurality of second electrodes CTH disposed on the display panel 100 and the cover member 155, and a change in a second capacitance C2 between the plurality of second electrodes CTH and the plurality of signal wirings M_SL can be detected and provided to the driving chip 210. And the driving chip 210 can perform a touch control function to provide a control signal for operation according to the touch input to a plurality of light-emitting elements. On one side facing opposite to the cover member 155 a grounding part GND can be disposed.

Such touch sensing method of a capacitance substrate can include a self-capacitance driving method and a mutual capacitance driving method in which a touch is sensed by detecting a change in capacitance between two types of touch sensors.

The display device 10 according to an embodiment of the present disclosure can perform touch driving and touch sensing in a self-capacitance-based touch sensing manner, or can perform touch driving and touch sensing in a mutual-capacitance-based touch sensing manner.

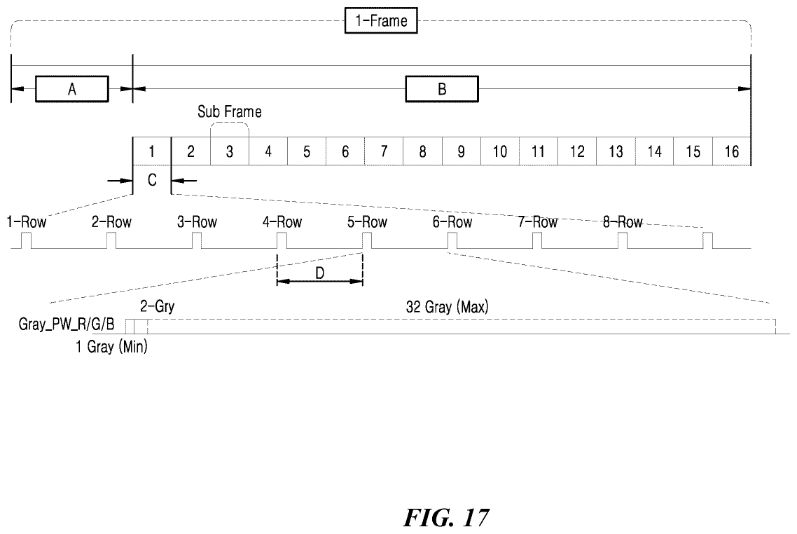

FIG. 17 is a diagram illustrating, by way of example, a signal waveform diagram when driving a display device according to an embodiment of the present disclosure.

Referring to FIG. 17, the display device according to an embodiment of the present disclosure can perform an emission operation in units of one frame 1-Frame.

One frame 1-Frame can include a touch section A and a display section B.

One frame 1-Frame can operate at a frequency of, for example, 60 Hz. In this case, the touch section A can operate for a first time period at a frequency of, for example, 60 Hz, and the display section B can operate for a second time period longer than the first time period at a frequency of, for example, 60 Hz. Therefore, the operation time of the touch section A and the operation time of the display section B within one frame 1-Frame can be different from each other. For example, the operation time of the touch section A can be shorter than the operation time of the display section B.

The display section B can include sixteen sub-frames Sub Frame.

For example, in a display panel, if eight micro light-emitting elements μLED are connected to each anode electrode line, which is the first electrode, one sub-frame section C can include eight pulse signals 1-Row, 2-Row, 3-Row, 4-Row, 5-Row, 6-Row, 7-Row, 8-Row. For example, the embodiment of the present disclosure can operate eight micro light-emitting element μLED during one sub-frame Sub Frame.

Therefore, in the embodiment of the present disclosure, since one frame 1-Frame includes sixteen sub-frames Sub Frame, and one sub-frame Sub Frame includes eight pulse signals, 128 micro light-emitting elements μLED can operate during one frame 1-Frame.

The embodiment of the present disclosure is not limited thereto. For example, if sixteen micro light-emitting elements μLED are connected to one anode electrode line, which is the first electrode, one sub-frame section C can include sixteen pulse signals. In this case, 256 micro light-emitting element μLED can operate during one frame 1-Frame.

One pulse signal (e.g., 5-Row) drives one micro light-emitting element μLED. One pulse signal period D can include a high signal section and a low signal section. In this regard, the length of time of the low signal section can be greater than that of the high signal section.

In an embodiment of the present disclosure, the driving time of a micro light-emitting element μLED can be controlled through a light-emitting signal EM applied to a gate electrode of a light-emitting transistor T_{EM}.

The micro driver μDriver can control the application time of the light-emitting signal EM with the pulse width PW. For example, in a case where one pulse signal e.g., 5-Row is applied to the gate electrode of a light-emitting transistor T_{EM} with one pulse width PW, it can be called 1 Gray.

The micro driver μDriver can control the application time of the light-emitting signal EM by adjusting the pulse width PW from at least 1 Gray (Min) to at most 32 Gray (Max) for one pulse signal (e.g., 5-Row).

Therefore, the micro driver μDriver can control the light-emitting time of the micro light-emitting element μLED corresponding to each sub-pixel of red R, green G, or blue B by applying a pulse signal with a pulse width PW adjusted from at least 1 Gray (Min) to at most 32 Gray (Max) to the gate electrode of the light-emitting transistor T_{EM}.

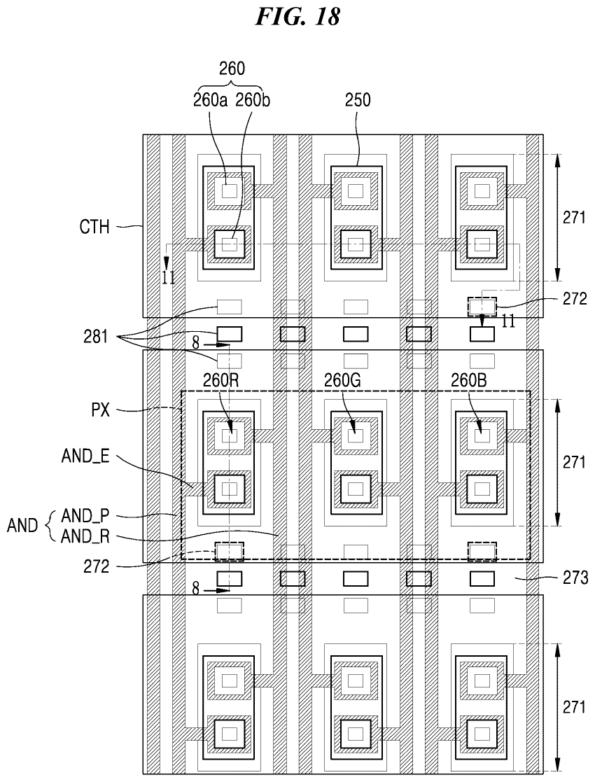

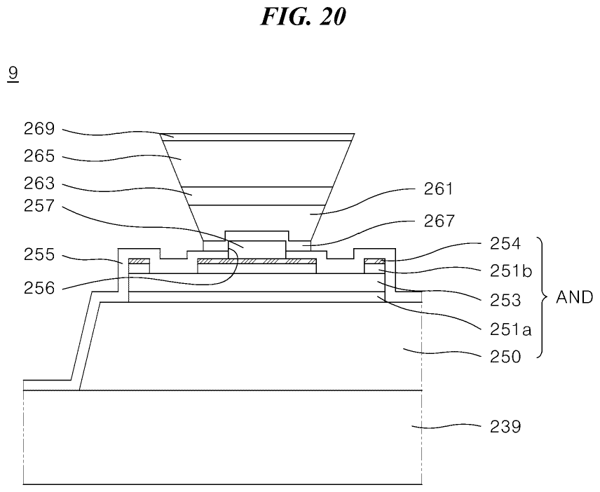

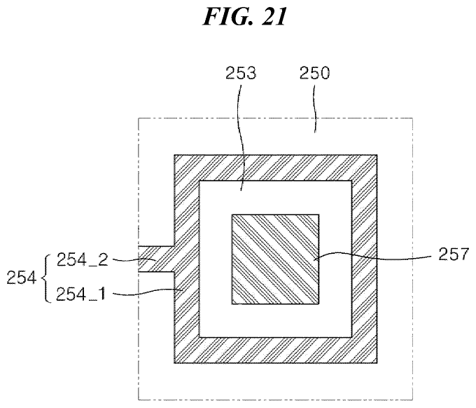

FIG. 18 is an enlarged plan view showing area 7 in FIG. 15 according to another embodiment of the present disclosure. FIG. 19 is a cross-sectional view taken along line 8-8 in FIG. 18. FIG. 20 is a cross-sectional view showing area 9 in FIG. 19. FIG. 21 is a plan view showing the bonding portion in FIG. 20. For convenience of explanation, FIG. 18 shows the first electrode AND, the second electrode CTH, a plurality of light-emitting elements 260, a bank 250, and optical insulating layers 271, 273.

Referring to FIGS. 18 to 20, the display device according to another embodiment of the present disclosure can include a plurality of first electrodes AND disposed on the substrate 200, bonding pads 257 disposed on the plurality of first electrodes AND, a plurality of light-emitting elements 260 electrically connected to the plurality of first electrodes AND, optical insulating layers 271, 273, a plurality of second electrodes CTH disposed on the plurality of light-emitting elements 260, and a contact electrode 274.

Each of the plurality of first electrodes AND can be arranged to be spaced apart from each other in the first direction of the substrate 200. The plurality of first electrodes AND can extend in a second direction intersecting the first direction. The first direction can be the X-axis direction of the substrate 200, and the second direction can be the Y-axis direction of the substrate 200; however, this is not exhaustive. For example, the first direction can be the horizontal direction or row direction of the substrate 200, and the second direction can be the vertical direction or column direction of the substrate 200.

The plurality of first electrodes AND can include a first line AND_P and a second line AND_R. The first line AND_P and the second line AND_R can be disposed to be spaced apart from each other in the first direction of the substrate 200. The first line AND_P and the second line AND_R can each include an extension portion AND_E electrically connected to the light-emitting element 260.

Each of the first line AND_P and the second line AND_R of the plurality of first electrodes AND can be connected to the bonding pad 257. The plurality of light-emitting elements 260 can be placed on the plurality of bonding pads 257.

On the plurality of light-emitting elements 260, the plurality of second electrodes CTH can be disposed. Each of the plurality of second electrodes CTH can be arranged to be spaced apart from each other in the second direction of the substrate 200.

The plurality of second electrodes CTH can extend in the first direction intersecting the second direction. The first direction can be the X-axis direction of the substrate 200, and the second direction can be the Y-axis direction of the substrate 200; however, this is not exhaustive. For example, the first direction can be the horizontal direction or row direction of the substrate 200, and the second direction can be the vertical direction or column direction of the substrate 200.

The plurality of first electrodes AND can be referred to as pixel electrodes. The plurality of second electrodes CTH can also be referred to as common electrodes. However, this is not exhaustive. For example, the plurality of first electrodes AND can be the first electrode CE1 in FIG. 8. Additionally, the plurality of second electrodes CTH can be the second electrode CE2 in FIG. 8.

On the substrate 200, a plurality of pixels PX can be disposed. Each of the plurality of pixels PX can be disposed with a separation area between them. A single pixel can include a plurality of sub-pixels that emit light of different colors. For example, the plurality of sub-pixels can include a first sub-pixel 260R that emits red light, a second sub-pixel 260G that emits green light, and a third sub-pixel 260B that emits blue light.

In the separation areas disposed between neighboring pixels PX, a plurality of opening areas 281 can be disposed. The plurality of opening areas 281 can be constituted by a light-blocking pattern 280, as shown in FIG. 19. The plurality of opening areas 281 can be disposed at positions corresponding to an ambient light sensor (ALS; Ambient Light System).

Referring to FIG. 19, the substrate 200 can be an insulating substrate including a flexible plastic or polymer material. For example, the substrate 200 can include a single-layer or multilayer structure including polyimide, polycarbonate, or polyethylene terephthalate; however, this is not exhaustive. The substrate 200 can be a silicon substrate or a glass substrate.

On the rear surface of the substrate 200, a carrier substrate 201 can be disposed. The carrier substrate 201 can be configured with a material that is relatively harder than the flexible substrate 200. The carrier substrate 201 can be omitted. Alternatively, the carrier substrate 201 can be removed thereafter.

On the front surface opposite to the rear surface of the substrate 200, a plurality of chip alignment patterns 203 can be disposed. The plurality of chip alignment patterns 203 can specify the location where the driving chip 210 is to be disposed. The plurality of chip alignment patterns 203 can include a metal material.

On the substrate 200 and the plurality of chip alignment patterns 203, a buffer layer 205 can be disposed. The buffer layer 205 can cover the plurality of chip alignment patterns 203 to planarizing the steps incurred by the plurality of chip alignment patterns 203. The buffer layer 205 can be formed by stacking a single layer or multiple layers of organic insulating material or inorganic insulating material. For example, the organic insulating material can include, but is not limited to, an acrylic resin or a photosensitive polyimide. The inorganic insulating material can include, but is not limited to, silicon oxide (SiOx) or silicon nitride (SiNx). The buffer layer 205 can include a multilayer structure in which the organic insulating and inorganic insulating materials are alternately stacked.

On the buffer layer 205, an adhesive layer 207 can be disposed. The adhesive layer 207 can include an acrylic adhesive material.

On the adhesive layer 207, the plurality of driving chips 210 can be disposed. The plurality of driving chips 210 can include a plurality of driving circuits to drive a plurality of light-emitting elements. Thus, the plurality of light-emitting elements can be driven according to the same control signal provided from the driving chip 210.

The plurality of driving chips 210 can include pad electrodes 211 on the upper side.

On the adhesive layer 207, there can be disposed a planarizing layer 220 covering a plurality of driving chips 210. The planarizing layer 220 can include a first planarizing layer 213 and a second planarizing layer 215. Between the first planarizing layer 213 and the second planarizing layer 215 a protective film 214 can be disposed.

The first planarizing layer 213 can be disposed to a thickness equivalent to a portion of the side surface of the plurality of driving chips 210. The first planarizing layer 213 can include an organic insulating material. For example, the first planarizing layer 213 can include, but is not limited to, a photo active compound (PAC).

The protective film 214 can include a first portion 214a disposed on an upper surface of the first planarizing layer 213, a third portion 214c disposed on an upper edge portion of each of the plurality of driving chips 210, and a second portion 214b disposed between the first portion 214a and the third portion 214c. The second portion 214b can connect the first portion 214a and the third portion 214c, and cover the side surface portion of each of the plurality of driving chips 210.

The protective film 214 can strengthen the adhesion between the plurality of driving chips 210 and the planarizing layer 220 to prevent a gap from occurring between the plurality of driving chips 210 and the planarizing layer 220. By preventing the occurrence of the gap, it is possible to prevent a problematic situation where moisture, chemical solutions or the like in the course of the manufacturing process penetrates into the plurality of drive chips 210. The protective film 214 can include an inorganic insulating material. For example, the protective film 214 can include silicon nitride (SiN).

The second planarizing layer 215 can be disposed on the protective film 214. The second planarizing layer 215 can include an opening hole exposing the pad electrodes 211 of a plurality of driving chips 210 while covering the third portions 214c of the protective film 214. The second planarizing layer 215 can include an organic insulating material. For example, the second planarizing layer 215 can include, but is not limited to, a photo active compound (PAC).

On the second planarizing layer 215, a plurality of wiring patterns 223 can be disposed. The plurality of wiring patterns 223 can be disposed on the same layer as the pad electrodes 211 of a plurality of driving chips 210. The plurality of wiring patterns 223 can also be referred to as a plurality of first-first connection wirings.

On the second planarizing layer 215, there can be disposed at least one insulating layer 225, 230, 235, 239 covering the plurality of driving chips 210. At least one or more insulating layers 225, 230, 235, 239 can include, but is not limited to, a first insulating layer 225, a second insulating layer 230, a third insulating layer 235, and a fourth insulating layer 239.

The first insulating layer 225 can be disposed on the second planarizing layer 215, and include first contact holes 226 that exposes pad electrodes 211 of each of the plurality of driving chips 210 and the plurality of wiring patterns 223. The second insulating layer 230 can be disposed on the first insulating layer 225, and include a second contact hole 232. The third insulating layer 235 can be disposed on the second insulating layer 230, and include a third contact hole 236. The fourth insulating layer 239 can be disposed on the third insulating layer 235, and include a fourth contact hole 240. The first contact hole 226, the second contact hole 232, the third contact hole 236, and the fourth contact hole 240 can be disposed so as not to overlap each other in the up and down direction; however, this is not exhaustive.

Each of at least one or more insulating layers 225, 230, 235, 239 can include a plurality of signal wirings 227, 233, 237, 241 electrically connecting a plurality of driving chips 210 and a plurality of light-emitting elements 260.

The plurality of signal wirings 227, 233, 237, 241 can include a first signal wiring 227, a second signal wiring 233, a third signal wiring 237, and a fourth signal wiring 241.

The first signal wiring 227 can be disposed on the first contact hole 226 of the first insulating layer 225, and electrically connected to the pad electrode 211 and the plurality of wiring patterns 223. The second signal wiring 233 can be disposed on the second contact hole 232 of the second insulating layer 230, and electrically connected to the first signal wiring 227. The third signal wiring 237 can be disposed on the third contact hole 236 of the third insulating layer 235, and electrically connected to the second signal wiring 233. The fourth signal wiring 241 can be placed on the fourth contact hole 240 of the fourth insulating layer 239, and electrically connected to the third signal wiring 237.

The first signal wiring 227, the second signal wiring 233, the third signal wiring 237, and the fourth signal wiring 241 can be connected to each other in the up and down direction to electrically connect the plurality of driving chips 210 and the plurality of light-emitting elements 260. The fourth signal wiring 241 can be electrically connected to the second electrode CTH. Accordingly, the control signals provided from the plurality of driving chips 210 can be transmitted to the plurality of light-emitting elements 260 to drive them.

When forming the plurality of signal wirings 227, 233, 237, 241, at least one of a plurality of alignment key patterns 101, 103 shown in FIG. 14 can be formed together. For example, when forming the third signal wiring 237 and the fourth signal wiring 241, the plurality of second alignment key patterns 103 can be formed.

On the fourth insulating layer 239, a plurality of bank layers 250 can be disposed. The plurality of bank layers 250 can distinguish neighboring sub-pixels from each other. The bank layer can also be referred to as a bank.

On the plurality of bank layers 250, the plurality of first electrodes AND can be disposed. On the plurality of first electrodes AND, there can be disposed the plurality of light-emitting elements 260 electrically connected to the plurality of first electrodes AND via the bonding pads 257. The bonding pad 257 can also be referred to as a solder pattern.

On each of the plurality of bank layers 250, at least one or more light-emitting elements 260 can be disposed. For example, on one bank layer 250 two light-emitting elements 260a, 260b emitting the same color can be disposed. One of the two light-emitting elements 260a, 260b can be a main light-emitting element 260a, and the other one thereof can be a redundant light-emitting element 260b.

Referring to FIG. 20, on the first electrode AND, the bonding pad 257 can be disposed. The bonding pad 257 can be configured with, but is not limited to, TiO₂ or tin (Sn), or an alloy thereof. For example, the bonding pad 257 can be a solder pattern SDP, see FIG. 9. The bonding pad 257 can be connected with the first connection electrode 267 of the light-emitting element 260. The first connection electrode 267 can be referred to as an anode electrode.

The first electrode AND can include a multilayer structure including a first metal layer 251a, a second metal layer 253, a third metal layer 251b, and a fourth metal layer 254. For example, each component of the first electrode AND can be identical to each component of the first electrode CE1 in FIG. 9. For example, the first metal layer 251a can be the first conductive layer CE1a, and the second metal layer 253 can be the second conductive layer CE1b. Additionally, the third metal layer 251b can be the third conductive layer CE1c, and the fourth metal layer 254 can be the fourth conductive layer CE1d.

The second metal layer 253 can have some areas exposed by patterning the fourth metal layer 254 and the third metal layer 251b. For example, referring to FIG. 21, the second metal layer 253 can have a shape that surrounds four sides of the bonding pad 257 to which the light-emitting element 260 is connected. The fourth metal layer 254 can include a first pattern 254-1 surrounding the outer sides of the second metal layer 253 when viewed from a plan view, and a second pattern 254-2 extending to the bank layer 250. The second pattern 254-2 of the fourth metal layer 254 can extend along one side surface of the bank layer 250. The second pattern 254-2 of the fourth metal layer 254 can be the extension portion AND_E of the first electrode AND; however, this is not exhaustive. For example, the extension portion AND_E of the first electrode AND can be a multilayer structure including the first metal layer 251a, the second metal layer 253, the third metal layer 251b, and the fourth metal layer 254.

The passivation layer 255 can be disposed on the first electrode AND, the bank layer 250, and the fourth insulating layer 239. The passivation layer 255 can include an opening hole that exposes the bonding pad 257.

Each of the plurality of light-emitting elements 260 can be disposed on the bonding pad 257 to be electrically connected thereto. The light-emitting element 260 can be a micro light-emitting element μLED, which is a micro-sized light-emitting element.

The light-emitting element 260 can include a first semiconductor layer 261, an active layer 263 sequentially deposited on one surface of the first semiconductor layer 261, and a second semiconductor layer 265. On one surface of the first semiconductor layer 261 a first connection electrode 267 can be disposed, and on one surface of the second semiconductor layer 265 a second pad electrode 269 can be disposed. The first pad electrode 267 can be an anode electrode, and the second pad electrode 269 can also be referred to as a cathode electrode.

Referring again to FIGS. 18 and 19, on the passivation layer 255, there can be disposed the optical insulating layer 271, 273 covering the plurality of light-emitting elements 260 and the bank layer 250. The optical insulating layer 271, 273 can include a first optical insulating layer 271 and a second optical insulating layer 273. The first optical insulating layer 271 can be referred to as a first optical layer, and the second optical insulating layer 273 can be referred to as a second optical layer.

The first optical insulating layer 271 can cover the bank layer 250, some areas of the passivation layer 255, and the area between the plurality of light-emitting elements 260. For example, the first optical insulating layer 271 can cover each sub-pixel of a plurality of sub-pixels. The first optical insulating layer 271 can inclusively cover at least the emission area EA.

The second optical insulating layer 273 can cover the remaining area except for the area where the first optical insulating layer 271 is disposed. Thus, the first optical insulating layer 271 can be implemented in an island shape divided for each sub-pixel.

The first thickness of the first optical insulating layer 271 can be smaller than the second thickness of the second optical insulating layer 273. Thus, when viewed from a flat surface, the area where the first optical insulating layer 271 is disposed can include a concave portion that is recessed inward more than the upper surface of the second optical insulating layer 273.

The first optical insulating layer 271 can include an organic insulating material having a plurality of scattering particles dispersed therein. For example, the plurality of scattering particles can include, but are not limited to, titanium dioxide (TiO₂) particles. The organic insulating material can include a siloxane resin. The first optical insulating layer 271 can scatter light incident from the plurality of light-emitting elements 260 by the plurality of scattering particles, and allow the scattered light to be emitted toward the light-emitting area EA. The light extraction efficiency can be improved by scattering the light with the scattering particles.

The second optical insulating layer 273 can be an organic insulating material surrounding the first optical insulating layer 271. The second optical insulating layer 273 can be an organic insulating material that includes no scattering particles. For example, the second optical insulating layer 273 can include a siloxane resin.

The second electrode CTH can be disposed on the plurality of light-emitting elements 260. The second electrode CTH can include a transparent conductive oxide such as indium tin oxide ITO, indium zinc oxide IZO or the like. The second electrode CTH can be disposed in contact with the second pad electrode 269 of each of the plurality of light-emitting elements 260.

The second electrode CTH can extend continuously in the first direction of the substrate 200. As a result, it can be commonly connected to a plurality of pixels PX arranged in the first direction of the substrate 200.

The second electrode CTH can be continuously extended over the second optical insulating layer 273, the first optical insulating layer, and the light-emitting element 260. The area where the first optical insulating layer 271 is disposed can include a concave portion that is recessed inward more than the upper surface of the second optical insulating layer 273. Accordingly, the first portion of the second electrode CTH disposed on the first optical insulating layer 271 is disposed along the concave portion, and thus can be disposed at a lower position than the second portion of the second electrode CTH disposed on the second optical insulating layer 273.

On the second electrode CTH, the upper diffusion film 275 can be disposed. The upper diffusion film 275 can include an organic insulating material having a plurality of scattering particles dispersed therein. For example, the plurality of scattering particles can include, but are not limited to, titanium dioxide (TiO₂) particles. The organic insulating material can include a siloxane resin. The upper diffusion film 275 can include, but is not limited to, the same material as the first optical insulating layer 271. The upper diffusion film 275 can also be referred to as a third optical layer.

The refractive index of the upper diffusion film 275 can range from 1.50 to 1.55. In one example, the refractive index of the upper diffusion film 275 can be 1.53.

The upper diffusion film 275 can scatter light incident from a plurality of light-emitting elements 260 by the plurality of scattering particles, and allow the scattered light to be emitted to the outside. The light extraction efficiency of the display device can be improved by scattering the light with the scattering particles. Accordingly, the display device can be driven at low power.

On the upper diffusion film 275, a light-blocking pattern 280 can be disposed. The light-blocking pattern 280 can be, but is not limited to, an organic insulating material including a black pigment. The light-blocking pattern 280 can fill the contact hole 272 disposed on the second optical insulating layer 273. The light-blocking pattern 280 can be referred to as a black matrix.

The light-blocking pattern 280 can cover a redundant light-emitting element 260b in one sub-pixel in a case where a main light-emitting element 260a operates normally. As another example, in a case where the main light-emitting element 260a is defective, the light-blocking pattern 280 can include an opening area exposing the redundant light-emitting element 260b.

The light-blocking pattern 280 can include a plurality of opening areas 281. When forming the light-blocking pattern 280 having the plurality of opening areas 281 disposed therein, the plurality of first alignment key patterns 101 can be formed as shown in FIG. 14. For example, during a process for patterning the plurality of opening areas 281, the second alignment key pattern 101 can be formed. The first alignment key pattern 101 can be a pattern for alignment between the display panel 100 and the cover member 155 of FIG. 1.

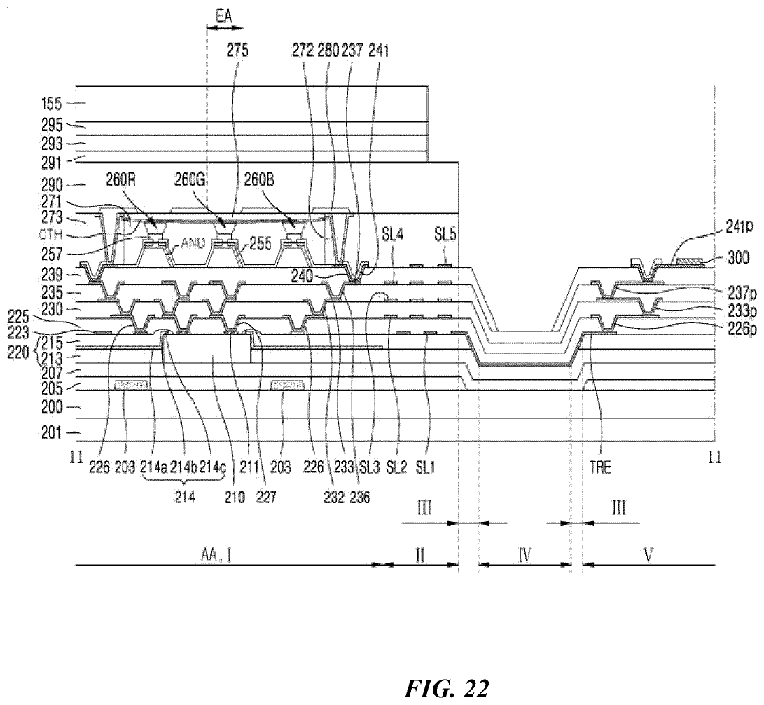

FIG. 22 is a cross-sectional view taken along line 11-11 in FIG. 14. In FIG. 22, the same reference symbols will be given to the same components as those described with reference to FIGS. 14 to 21, and the description thereof will be simplified or omitted. Additionally, a plurality of light-emitting elements 260R, 260G, 260B are shown in the direction of cut line 11-11 in FIG. 18.

Referring to FIG. 22, the display panel can include a display area AA, I, a fan-out area II, a bending area IV, a taper area III, and a pad area V. The fan-out area II and the taper area III can be disposed in the first non-display area NA1, see FIG. 8, and the pad area V can be disposed in the second non-display area NA2, see FIG. 8.

In the display area AA, I, the plurality of light-emitting elements 260R, 260G, 260B and a plurality of driving chips 210 electrically connected to the plurality of light-emitting elements 260R, 260G, 260B can be disposed. In order to electrically connect the plurality of light-emitting elements 260R, 260G, 260B and the plurality of driving chips 210, a plurality of signal wirings 227, 233, 237, 241 can be formed and disposed on each of at least one or more insulating layers 225, 230, 235, 239. The plurality of signal wirings 227, 233, 237, 241 can include a first signal wiring 227, a second signal wiring 233, a third signal wiring 237, and a fourth signal wiring 241. However, this is not exhaustive. For example, the first signal wiring 227, the second signal wiring 233, the third signal wiring 237, and the fourth signal wiring 241 can be referred to as the first-second connection wiring, the first-third connection wiring, the first-fourth connection wiring, and the contact electrode, respectively.

The plurality of light-emitting elements 260R, 260G, 260B can be covered with the first optical insulating layer 271. On the plurality of light-emitting elements 260R, 260G, 260B and the first optical insulating layer 271, the second electrode CTH can be disposed. On the second electrode CTH there can be the upper diffusion film 275 having the plurality of scattering particles dispersed therein.

On the upper diffusion film 275, a light-blocking pattern 280 can be disposed. On the light-blocking pattern 280 and the upper diffusion film 275, a first overcoating layer 290 can be disposed. The first overcoating layer 290 will be described later. The first overcoating layer 290 can be referred to as a cover layer.

On the first overcoating layer 290, a polarizing layer 293 can be disposed via a first adhesive layer 291. On the polarizing layer 293, the cover member 155 can be disposed via a second adhesive layer 295.

The fan out area II can be an area in which a plurality of link wirings SL1, SL2, SL3, SL4, SL5 extending a plurality of wiring patterns 223 and the plurality of signal wirings 227, 233, 237, 241 disposed on the display area AA to the pad area V are disposed. The plurality of link wirings SL1, SL2, SL3, SL4, SL5 can be disposed in different layers of at least one or more insulating layers 225, 230, 235, 239.

The plurality of link wirings SL1, SL2, SL3, SL4, SL5 can include a first link wiring SL1, a second link wiring SL2, a third link wiring SL3, a fourth link wiring SL4, and a fifth link wiring SL5.

The plurality of link wirings SL1, SL2, SL3, SL4, SL5 can respectively be formed together with the plurality of wiring patterns 223 and the plurality of signal wirings 227, 233, 237, 241, and be disposed on the same layer. For example, the first link wiring SL1 can be disposed in the same layer as the plurality of wiring patterns 223, and the second link wiring SL2 can be disposed in the same layer as the first signal wiring 227. Additionally, the third link wiring SL3 can be disposed on the same layer as the second signal wiring 233, and the fourth link wiring SL4 can be disposed on the same layer as the fourth signal wiring 237. Additionally, the fifth link wiring SL5 can be disposed on the same layer as the fifth signal wiring 241.

Among the plurality of link wirings SL1, SL2, SL3, SL4, SL5, a portion of the first link wiring SL1 can extend to the pad area V through the bending area IV; however, this is not exhaustive. For example, the plurality of link wirings SL1, SL2, SL3, SL4, SL5 can extend to the pad area V through the bending area IV. The portion of the first link wiring SL1 extending to the pad area V can be defined as a signal connection wiring TRE.

On the substrate 200 in the bending area IV, there can be disposed a layer-stacking structure including the adhesive layer 207, the first planarizing layer 213, the plurality of signal connection wirings TRE, the first insulating layer 225, the second insulating layer 230, and the third insulating layer 235. The bending area IV can have a relatively smaller thickness than the fan-out area II.

The pad area V can include a first pad wiring 226p, a second pad wiring 233p, a third pad wiring 237p, and a fourth pad wiring 241p that are electrically connected with the signal connection wiring TRE extending from the display area AA, I. On the fourth pad wiring 241p, a pad portion 300 can be disposed. The pad portion 300 can be connected to the flexible circuit board 157 in FIG. 14 to be connected with the printed circuit board 160. Various signals can be transmitted from the printed circuit board 160 to the display area AA, I through the pad portion 300, or various signals can be provided from the display area AA, I to the printed circuit board 160.

The first pad wiring 226p, the second pad wiring 233p, the third pad wiring 237p, and the fourth pad wiring 241p can be formed at the same time when forming the plurality of signal wirings 227, 233, 237, 241, and be disposed on the same layer. For example, the first pad wiring 226p can be disposed on the same layer as the first signal wiring 227, and the second pad wiring 233p can be disposed on the same layer as the second signal wiring 233. Additionally, the third pad wiring 237p can be disposed on the same layer as the third signal wiring 237, and the fourth pad wiring 241p can be disposed on the same layer as the fourth signal wiring 241.

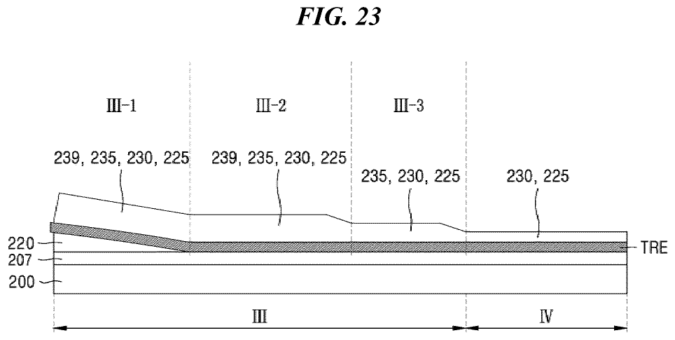

Meanwhile, in order to prevent the bonding properties of one or more insulating layers from being degraded and causing defects such as delamination or cracks during the bending operation in the bending area IV, the thicknesses of the insulating layers can be gradually reduced in the taper area III. Hereinafter, description will be given with reference to FIG. 23.

FIG. 23 is an enlarged cross-sectional view of a tapered area according to another embodiment of the present disclosure.

Referring to FIG. 23, the tapered area III according to another embodiment of the present disclosure can be a section where the thickness difference between the fan-out area II and the bending area IV is gradually alleviated. The taper area III can include a first step alleviation area III-1, a second step alleviation area III-2, and a third step alleviation area III-3.

In another embodiment, the first step alleviation area III-1 can be an area closest to the fan-out area II. For example, on the substrate 200 in the first step alleviation area III-1, there can be disposed a first layer-stacking structure including the adhesive layer 207, the planarizing layer 220, the signal connection wiring TRE, the fourth insulating layer 239, the third insulating layer 235, the second insulating layer 230, and the first insulating layer 225. Thus, it has a first thickness which is greatest.

On the substrate 200 in the second step alleviation area III-2, there can be disposed a second layer-stacking structure including the adhesive layer 207, the signal connection wiring TRE, the fourth insulating layer 239, the third insulating layer 235, the second insulating layer 230, and the first insulating layer 225. In the second step alleviation area III-2, the planarizing layer 220 can be omitted. Thereby, the second step alleviation area III-2 can have a second thickness smaller than the first thickness. On the substrate 200 in the third step alleviation area III-3, there can be disposed a third layer-stacking structure including the adhesive layer 207, the signal connection wiring TRE, the third insulating layer 235, the second insulating layer 230, and the first insulating layer 225. In the third step alleviation area III-3, the fourth insulation layer 239 can be omitted. Thereby, the third step alleviation area III-3 can have a third thickness smaller than the second thickness.

On the substrate 200 in the bending area IV, there can be disposed a fourth layer-stacking structure including the adhesive layer 207, the signal connection wiring TRE, the second insulating layer 230, and the first insulating layer 225. In the bending area IV, the fourth insulating layer 239 and the third insulating layer 235 can be omitted. Thereby, the bending area IV can have a fourth thickness which is smaller than the third thickness, and is smallest.

The layer-stacking structures of insulating layers can be disposed so that the thickness gradually becomes smaller as it goes from the taper area III to the bending area IV. In the bending area IV, the bonding properties between one or more insulating layers can be prevented from being degraded during a bending operation. Accordingly, it is possible to prevent defects such as delamination, cracks or the like between one or more insulating layers. As a result, it is possible to prevent the defects which can occur when moisture penetrates into the signal connection wiring TRE through cracks or the like, causing the short circuit or disconnection of the signal connection wiring TRE.

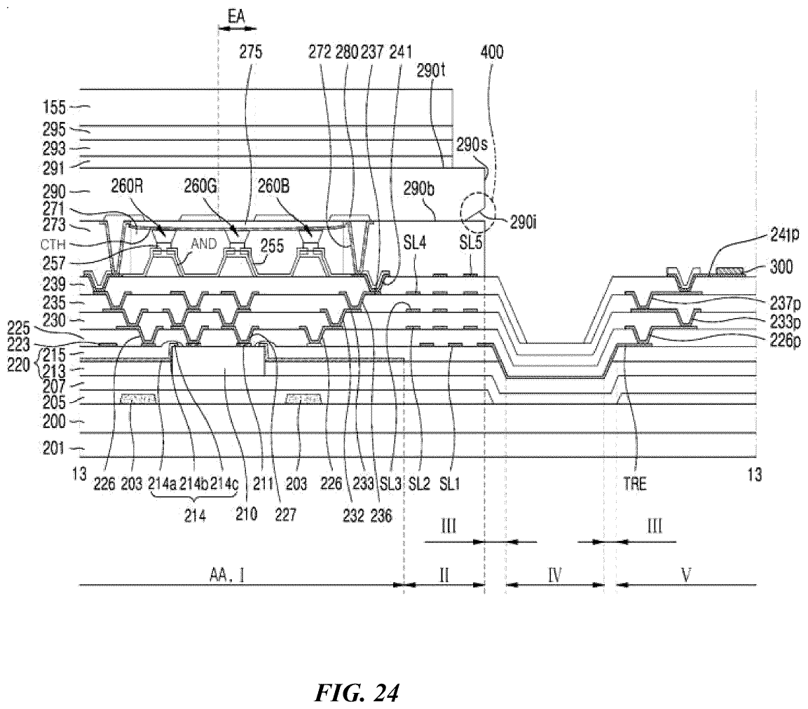

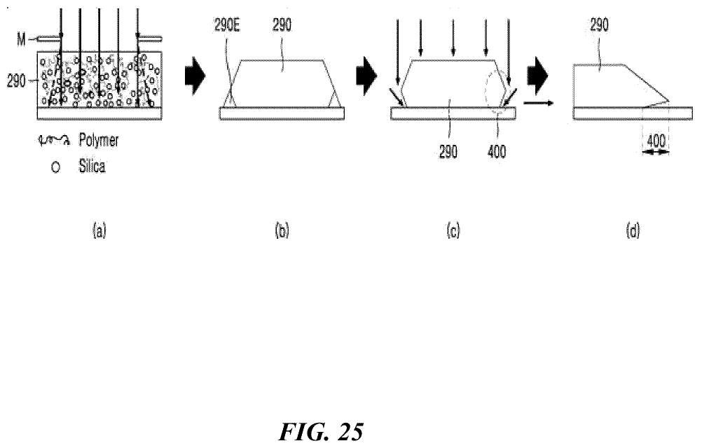

FIG. 24 is a cross-sectional view taken along cut line 13-13 in FIG. 14, of a display device according to another embodiment of the present disclosure. FIG. 25 is a view illustrating the mechanism by which an undercut section occurs. In FIG. 24, the same reference symbols will be given to the same components as those described with reference to FIGS. 14 to 23, and the duplicate description thereof will be omitted or may be briefly provided.

Referring to FIG. 24, on the light-blocking pattern 280 and the optical insulating layer 271, 273, the first overcoating layer 290 can be disposed. On the first overcoating layer 290, a polarizing layer 293 can be disposed via a first adhesive layer 291. On the polarizing layer 293, the cover member 155 can be disposed via a second adhesive layer 295.

The first overcoating layer 290 can cover at least an area where the plurality of light-emitting elements 260R, 260G, 260B are disposed. One surface of the first overcoating layer 290 can be disposed in contact with the upper diffusion film 275. The first overcoating layer 290 can extend to the fan-out area II while covering the display area AA, I; however, this is not exhaustive.

The first overcoating layer 290 can include an organic insulating material. The first overcoating layer 290 can include a first polymer insulating material having a plurality of scattering particles dispersed therein. For example, the first polymer insulating material can include an organosiloxane resin, and the plurality of scattering particles can include hollow silica. The hollow silica has particles with empty space on the surface and in the inside, so they have a relatively lower refractive index compared to solid particles with a filled inside. Accordingly, the organosiloxane resin having hollow silica dispersed therein can have a relatively lower refractive index than a single substance of the organosiloxane resin.

The first overcoating layer 290 can have a first refractive index relatively smaller than the refractive index of the upper diffusion film 275. The first refractive index of the first overcoating layer 290 can be less than 1.4. The first refractive index can range from 1.37 to 1.39. In one example, the refractive index of the first overcoating layer 290 can be 1.38.

Light emitted from the plurality of light-emitting elements 260R, 260G, 260B as light sources can pass through the upper diffusion film 275, the first overcoating layer 290, the polarizing layer 293, and the cover member 155 to be emitted to the outside.

A portion of the light incident on the polarizing layer 293, whose angle of incidence is greater than the total reflection angle, is not emitted to the outside, but is perished by total internal reflection. As the amount of light undergoing the total internal reflection in the polarizing layer 293 increases, the amount of light that is perished also increases, thus decreasing the light extraction efficiency. In view of the above, the light needs to be incident on the polarizing layer 293 at an angle of incidence smaller than the total reflection angle to reduce the amount of the light undergoing the total internal reflection in the polarizing layer 293.

To this end, the first overcoating layer 290 having a first refractive index lower than the refractive index of the upper diffusion film 275 can be disposed. By disposing the first overcoating layer 290 whose refractive index is smaller than that of the upper diffusion film 275, the proportion of light undergoing total reflection at the boundary can be increased.

Light that is totally reflected at the boundary surface of the upper diffusion film 275 can be incident on the polarizing layer 293 through light recycling such as a re-reflection process. In this case, light incident on the polarizing layer 293 is incident at an angle of incidence smaller than the total reflection angle, so that the amount of light undergoing the total internal reflection in the polarizing layer 293 can be reduced. As a result, the amount of light emitted to the outside from the polarizing layer 293 increases, thereby improving the light extraction efficiency.

However, the first overcoating layer 290 having a low refractive index can have an undercut section 400 formed along the edge.

Referring to FIG. 25, the undercut section 400 can be formed as a difference in the degree of curing occurs between respective areas of the first overcoating layer 290 during the photo process performed to pattern the first overcoating layer 290, and the edge portion is removed.

The mask M including an opening can be disposed on the first overcoating layer 290, and a photolithography process can be performed (FIG. 25(a)). The area corresponding to the opening can be an area where the first overcoating layer 290 remains. The area corresponding to the mask M can be an area where the first overcoating layer 290 is removed. For example, the area corresponding to the mask M can be the outer side of the edge portion of the first overcoating layer 290.

The first overcoating layer 290 can include a first polymer insulating material having a plurality of scattering particles dispersed therein. The first polymer insulating material can include an organosiloxane resin, and the plurality of scattering particles can include hollow silica.

When the photolithography process is performed on the first overcoating layer 290 through the opening in the mask M, the area corresponding to the opening can be irradiated with an exposure amount required for curing. However, diffracted light can be transmitted to some areas of the portion blocked by the mask M. In the portion of the first overcoating layer 290, through which the diffracted light is transmitted, as it goes toward the lower end, the diffracted light is perished, resulting in the decreased exposure amount compared to the upper end. For example, the exposure amount can be further decreased in the lower end portion as the light is scattered by the plurality of scattering particles dispersed within the first polymer insulating material.

The portion of the first overcoating layer 290 which has been subjected to the exposure can be cured by performing a heat treatment as a post-exposure process (FIG. 25(b)). The area corresponding to the opening of the mask M can be completely cured as it is subjected to the sufficient exposure amount. However, the portion blocked by the mask M, through which the diffracted light is transmitted, can be subjected to the insufficient exposure amount, resulting in the insufficient curing degree. For example, the edge portion 290E of the first overcoating layer 290 can have insufficient curing degree.

If a development process is performed using a developing solution in a state where the curing degree of the edge portion 290E is insufficient (FIG. 25(c)), the edge portion 290E can be removed by the developing solution, forming the undercut section 400 (FIG. 25(d)).

The undercut section 400 can become a penetration path susceptible to moisture penetration, or can cause cracks to occur in the first overcoating layer 290 in a subsequent process.

In order to prevent the undercut section 400, the first overcoating layer 290 would be formed so as to have no scattering particle dispersed therein, which would lead to a high refractive index, and, however, the light extraction efficiency would decrease.

For example, if the first overcoating layer 290 with a high refractive index, in which no scattering particle is dispersed, is disposed on the upper diffusion film 275, there would be no difference in refractive index between the upper diffusion film 275 and the first overcoating layer 290, so that most of the light would not be totally reflected at the boundary surface of the upper diffusion film 275. Then, the amount of light undergoing the total internal reflection in the polarizing layer 293 would increase, and so, the amount of light that is perished would increase, resulting in the decreased light extraction efficiency.

In view of the above, another embodiment of the present disclosure provides a multilayer structure in which a plurality of overcoating layers are formed so as to have different refractive indices to improve light extraction efficiency while preventing defects caused by the undercut section.

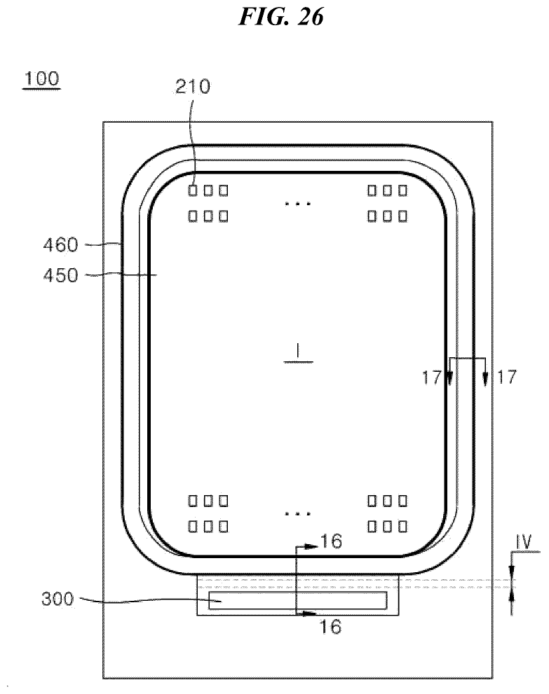

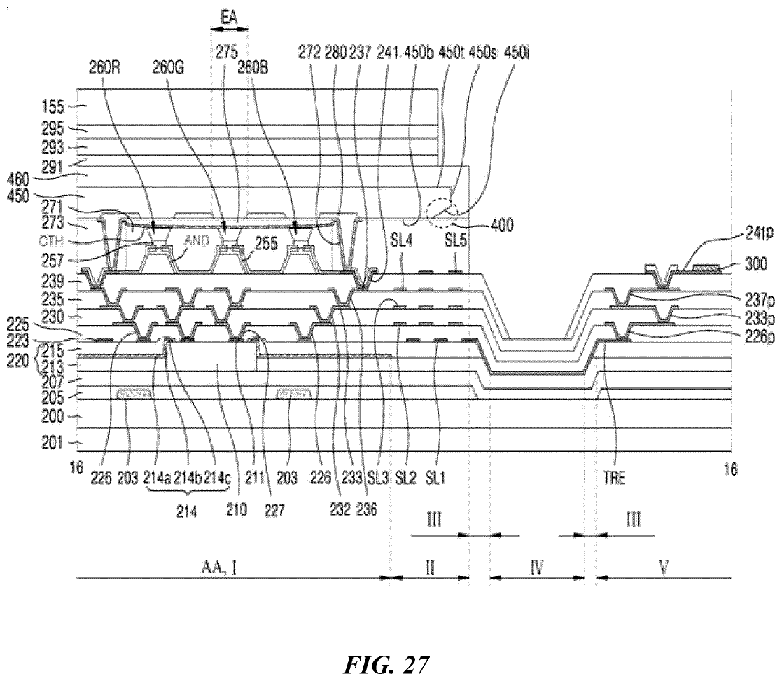

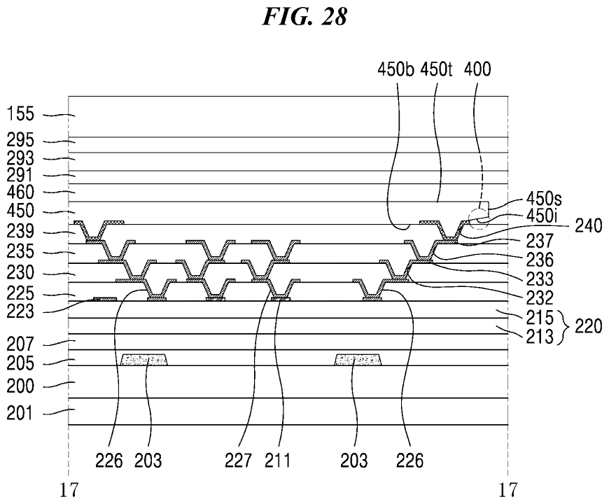

FIG. 26 is a plan view showing a display panel of a display device according to another embodiment of the present disclosure. FIG. 27 is a cross-sectional view taken along cut line 16-16 in FIG. 26. FIG. 28 is a cross-sectional view taken along cut line 17-17 in FIG. 26.

For convenience of explanation, in FIG. 26, a plurality of driving chips 210, a first overcoating layer 450, and a second overcoating layer 460 are illustrated on the display panel 100. In FIGS. 26 to 28, the same reference symbols will be given to the same components as those described with reference to FIGS. 14 to 23, and the duplicate description thereof will be omitted or may be briefly provided.

Referring to FIGS. 26 to 28, on the light-blocking pattern 280 and the optical insulating layer 271, 273, the first overcoating layer 450 can be disposed. On the first overcoating layer 450, a second overcoating layer 460 can be disposed. On one surface of the second overcoating layer 460 a first adhesive layer 291 can be disposed. On the first adhesive layer 291, the polarizing layer 293 can be disposed. On the polarizing layer 293, the cover member 155 can be disposed via a second adhesive layer 295.

The display panel 100 can include upper, lower, left, and right sides. In the lower side direction adjacent to the bending area IV, the first overcoating layer 450 can be disposed on the display area AA, I and the non-display area outside the display area AA, I. In areas other than the bending area IV, for example, the upper, left, and right side directions, the first overcoating layer 450 can be disposed in the non-display area outside the display area AA, I.

Referring to FIG. 27, in the lower side direction adjacent to the bending area IV, the first overcoating layer 450 can be disposed on the light-blocking pattern 280 and the optical insulating layers 271, 273. The first overcoating layer 450 can cover at least an area where the plurality of light-emitting elements 260R, 260G, 260B are disposed. One surface of the first overcoating layer 450 can be disposed in contact with the upper diffusion film 275. The first overcoating layer 450 can extend to the fan-out area II while covering the display area AA, I; however, this is not exhaustive.

Referring to FIG. 28, in areas other than the bending area IV, for example, the upper, left, and right side directions, the first overcoating layer 450 can be disposed in the non-display area outside the display area AA, I. Thus, one surface of the first overcoating layer 450 can be disposed in contact with the fourth insulating layer 239 in the areas other than the bending area IV.

The first overcoating layer 450 can include an organic insulating material. The first overcoating layer 450 can include a first polymer insulating material having a plurality of scattering particles dispersed therein. For example, the first polymer insulating material can include an organosiloxane resin, and the plurality of scattering particles can include hollow silica.

The first refractive index of the first overcoating layer 450 can be relatively smaller than the refractive index of the upper diffusion film 275. The first refractive index of the first overcoating layer 290 can be less than 1.4. The first refractive index can range from 1.37 to 1.39. In one example, the refractive index of the first overcoating layer 450 can be 1.38.

Since the first refractive index of the first overcoating layer 450 has a low refractive index that is lower than the refractive index of the upper diffusion film 275, the total internal reflection at the interface between the upper diffusion film 285 and the first overcoating layer 450 increases, thereby improving the light emission efficiency. However, in a case of the first overcoating layer 450 with a low refractive index, in which no scattering particle is dispersed, the undercut section 400 can be formed along the edge portion.

The undercut section 400 can be formed along the lower surface of the edge portion of the outer end portion of the first overcoating layer 450. The undercut section 400 can be shaped to be recessed toward an inner side further than the outer end portion of the first overcoating layer 450. The first overcoating layer 450 in which the undercut section 400 is formed can include a lower surface 450b, an upper surface 450t opposite to the lower surface 450b, a side surface 450s connecting the lower surface 450b and the upper surface 450t, and an inclined surface 450i inclined from the side surface 450s toward the lower surface 450b.

The inclined surface 450i of the first overcoating layer 450 can have a straight shape, a curved shape, or an uneven shape.

The undercut section 400 can be a space located between the inclined surface 450i of the first overcoating layer 450 and the second optical insulating layer 273. Additionally, in the areas other than the bending area IV, the undercut section 400 can be a space located between the inclined surface 450i of the first overcoating layer 450 and the fourth insulating layer 239. In one example, the height of the undercut section 400 can decrease from the outer end portion of the first overcoating layer 450 toward the inner side.

The undercut section 400 can become a penetration path susceptible to moisture penetration, or can cause cracks to occur in the first overcoating layer 450 in a subsequent process.

For example, the undercut section 400 can be formed at a position overlapping with the fourth signal wiring 241 of the plurality of signal wirings 227, 233, 237, 241 on the display area I, which is disposed at the uppermost side. In this case, a portion of the surface of the fourth signal wiring 241 can be exposed by the undercut section 400. If moisture or the like penetrates into the exposed portion of the surface, the metal material of the fourth signal wiring 241 can oxidize and corrode. Thereby, signals may not be provided to the display area, problematically degrading the reliability of the display device.

In addition, when a physical impact is applied from the outside, a crack can occur in the undercut section 400, which is a space located between the inclined surface 450i of the first overcoating layer 450 and the second optical insulating layer 273. If the crack propagates toward the display area I, a defect will occur in the display area I.

In view of the above, according to an embodiment of the present disclosure, on the first overcoating layer 450 the second overcoating layer 460 can be disposed to prevent defects caused by the undercut section 400. The second overcoating layer 460 can fill the undercut section 400 formed along the edge portion of the first overcoating layer 450. For example, the undercut section 400 can be formed continuously along at least one edge portion of the first overcoating layer 450; however, this is not exhaustive. The undercut section 400 can be formed discontinuously along the edge portion of the first overcoating layer 450.

The edge portion can include upper, lower, left, and right edge portions.

The second overcoating layer 460 can be shaped to surround the edge portion of the first overcoating layer 450, which includes the undercut section 400. The first overcoating layer 450 and the second overcoating layer 460 can be in contact with each other. For example, the second overcoating layer 460 can be in contact at least with a portion of the upper surface 450t of the first overcoating layer 450, the side surface 450s connecting the lower surface 450b and the upper surface 450t, and the inclined surface 450i inclined from the side surface 450s toward the lower surface 450b.

The second overcoating layer 460 can include an extension portion protruding into the space disposed in the lower area of the edge portion of the first overcoating layer 450. The extension portion of the second overcoating layer 460 can be shaped to be inserted into the undercut section 400. The extension portion of the second overcoating layer 460 can be shaped to be recessed toward an inner side further than the outer end portion of the first overcoating layer 450.

The second overcoating layer 460 can be shaped to surround the edge portion of the first overcoating layer 450. Accordingly, the contact area of the second overcoating layer 460 in contact with the inclined surface 450i of the first overcoating layer 450 can increase. By increasing the contact area between the first overcoating layer 450 and the second overcoating layer 460, the bonding strength between different organic insulating layers can be increased. Thereby, it is possible to prevent the occurrence of defects caused by the delamination between the first overcoating layer 450 and the second overcoating layer 460.

The inclined surface 450i of the first overcoating layer 450 can have a straight shape, a curved shape, or an uneven shape. Accordingly, the contact area of the second overcoating layer 460 in contact with the inclined surface 450i of the first overcoating layer 450 can increase further.

The second overcoating layer 460 can include an organic insulating material. The second overcoating layer 460 can be a second polymer insulating material. For example, the second polymer insulating material can include an acrylic resin. The second overcoating layer 460 is deprived of a scattering particle within the second polymer insulating material to prevent an undercut section from occurring.

The second overcoating layer 460 can have a second refractive index relatively greater than the first refractive index of the first overcoating layer 450. The second refractive index of the second overcoating layer 460 can range from 1.5 to 1.6.

The second overcoating layer 460 has a higher refractive index than the first overcoating layer 450, thereby preventing an undercut section from occurring at the edge portion of the second overcoating layer 460. As a result, the reliability of the display device can be improved.

For example, in a photo process performed to pattern the second overcoating layer 460, the photolithography process can be performed disposing the mask. The area corresponding to the opening of the mask can be an area where the second overcoating layer 460 remains, and the area corresponding to the mask can be an area where the second overcoating layer 460 is removed. For example, the area corresponding to the mask can be the outer side of the edge portion of the second overcoating layer 460.

When the second overcoating layer 460 is irradiated with light through the opening of the mask, the area corresponding to the opening can be irradiated with the exposure amount required for curing. Additionally, the second overcoating layer 460 can be a second polymer insulating material having no scattering particle dispersed therein. As a result, a portion of the area blocked by the mask, through which the diffracted light is transmitted, can be irradiated with the exposure amount required for curing without decreasing the exposure amount.

In the heat treatment process after the photolithography process, the second overcoating layer 460 does not have a difference in the curing degree depending on the area, so even if the development process is performed, the edge portion thereof remains without being removed. Accordingly, it is possible to prevent an undercut section from occurring in the edge portion of the second overcoating layer 460.

As a result, according to another embodiment of the present disclosure, not only can the light extraction efficiency be improved, but also the undercut section can be prevented from becoming a cause of defects, thereby realizing a display device having reliability.

In another embodiment of the present disclosure, a configuration in which two layers, for example, the first overcoating layer 450 and the second overcoating layer 460, are stacked has been described; however, this is not exhaustive. For example, each of the first overcoating layer 450 and the second overcoating layer 450 can include three or more multilayers.

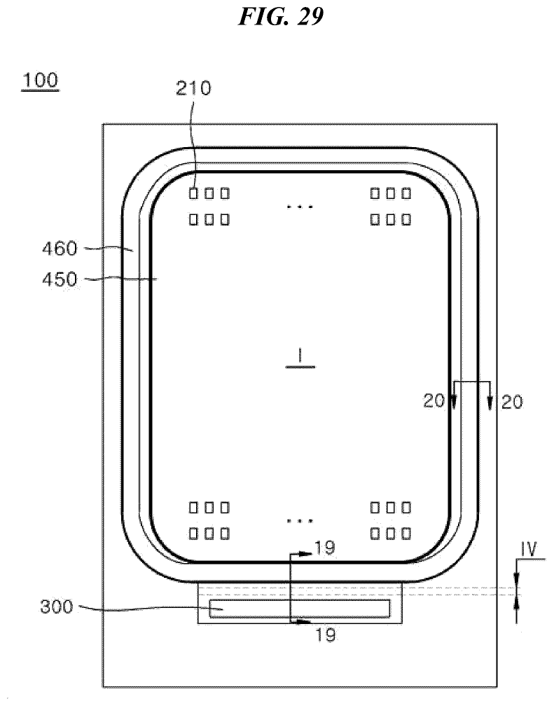

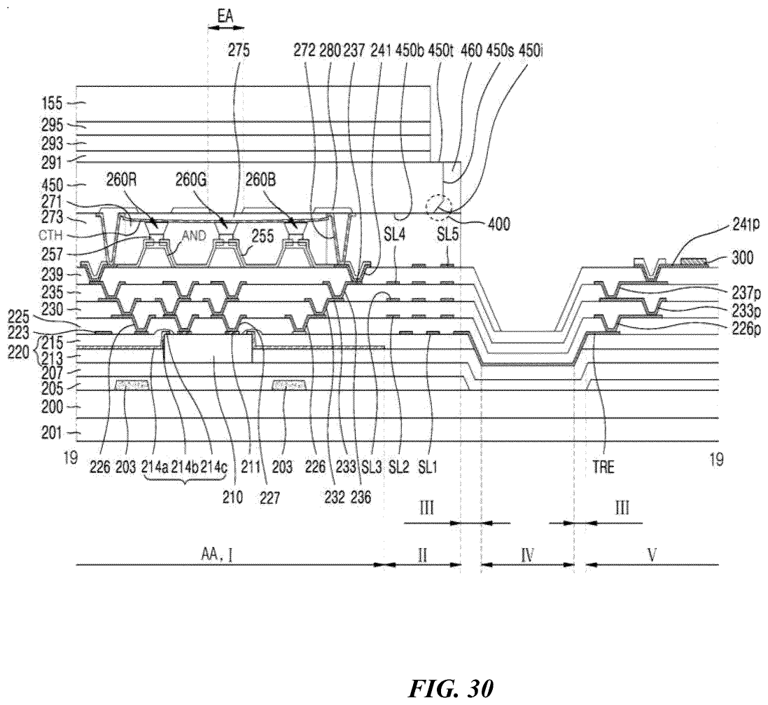

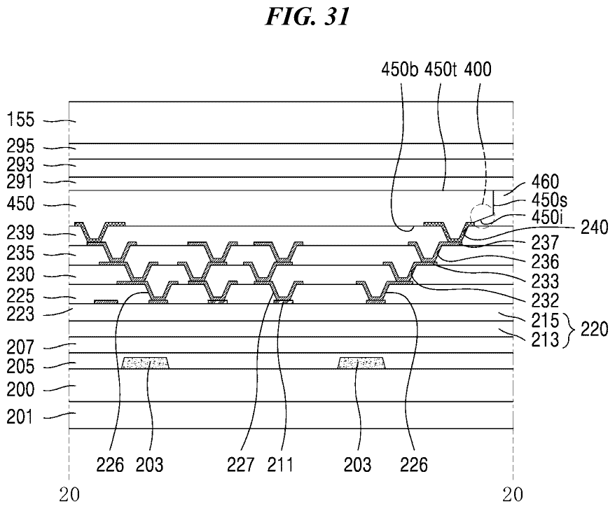

FIG. 29 is a plan view showing a display panel of a display device according to another embodiment of the present disclosure. FIG. 30 is a cross-sectional view taken along cut line 19-19 in FIG. 29. FIG. 31 is a cross-sectional view taken along cut line 20-20 in FIG. 29.

For convenience of explanation, in FIG. 29, driving chips 210, a first overcoating layer 450, and a second overcoating layer 460 are illustrated on the display panel 100. In FIGS. 29 to 31, the same reference symbols will be given to the same components as those described with reference to FIGS. 14 to 23, and the description thereof will be simplified or omitted.

Referring to FIGS. 29 to 31, on the display panel 100 the first overcoating layer 450 can be disposed. The display panel 100 can include upper, lower, left, and right sides. In the lower side direction adjacent to the bending area IV, the first overcoating layer 450 can be disposed on the display area AA, I and the non-display area outside the display area AA, I. In areas other than the bending area IV, for example, the upper, left, and right side directions, the first overcoating layer 450 can be disposed in the non-display area outside the display area AA, I.

Referring to FIG. 30, in the lower side direction adjacent to the bending area IV, the first overcoating layer 450 can be disposed on the light-blocking pattern 280 and the optical insulating layers 271, 273. The first overcoating layer 450 can cover at least an area where the plurality of light-emitting elements 260R, 260G, 260B are disposed. One surface of the first overcoating layer 450 can be disposed in contact with the upper diffusion film 275.

Referring to FIG. 31, in areas other than the bending area IV, for example, the upper, left, and right side directions, the first overcoating layer 450 can be disposed in the non-display area outside the display area AA, I. Thus, one surface of the first overcoating layer 450 can be disposed in contact with the fourth insulating layer 239 in the areas other than the bending area IV.

The first refractive index of the first overcoating layer 450 can be a low refractive index lower than the refractive index of the upper diffusion film 275. Thereby, the total internal reflection increases at the interface between the upper diffusion film 285 and the first overcoating layer 450, and thus, the light incident on the polarizing layer 293 can be incident at an angle of incidence smaller than the total reflection angle. Accordingly, the light perished by the total internal reflection in the polarizing layer 293 can be reduced, thereby improving the light emission efficiency. The first overcoating layer 450 with a low refractive index can have an undercut section 400 formed along the edge portion.

The undercut section 400 can be disposed along the lower surface of the edge portion of the outer end portion of the first overcoating layer 450. The undercut section 400 can be shaped to be recessed toward an inner side further than the outer end portion of the first overcoating layer 450. The first overcoating layer 450 in which the undercut section 400 is formed can include a lower surface 450b, an upper surface 450t opposite to the lower surface 450b, a side surface 450s connecting the lower surface 450b and the upper surface 450t, and an inclined surface 450i inclined from the side surface 450s toward the lower surface 450b.

Outside the end portion of the side surface 450b of the first overcoating layer 450, the second overcoating layer 460 can be disposed. In one example, the first overcoating layer 450 and the second overcoating layer 460 can have the same upper surface level. In another example, the second overcoating layer 460 can partially cover the edge portion of the upper surface 450t of the first overcoating layer 450.

The second overcoating layer 460 can fill the undercut section 400 formed along the edge portion of the first overcoating layer 450. For example, the undercut section 400 can be formed continuously along at least one edge portion of the first overcoating layer 450; however, this is not exhaustive. The undercut section 400 can be formed discontinuously along the edge portion of the first overcoating layer 450.

The first overcoating layer 450 and the second overcoating layer 460 can be in contact with each other. For example, the second overcoating layer 460 can be in contact at least with the side surface 450s connecting the lower surface 450b and the upper surface 450t of the first overcoating layer 450, and the inclined surface 450i inclined from the side surface 450s toward the lower surface 450b.

The second overcoating layer 460 can include an extension portion protruding into the space disposed in the lower area of the edge portion of the first overcoating layer 450. The extension portion of the second overcoating layer 460 can be shaped to be inserted into the undercut section 400. The extension portion of the second overcoating layer 460 can be shaped to be recessed toward an inner side further than the outer end portion of the first overcoating layer 450.

Since the second overcoating layer 460 is disposed along the outer side of the end portion of the side surface 450b of the first overcoating layer 450, the first adhesive layer 291 can be disposed on one surface of the first overcoating layer 450. On the first adhesive layer 291, the polarizing layer 293 can be disposed. On the polarizing layer 293, the cover member 155 can be disposed via a second adhesive layer 295.

According to another embodiment of the present disclosure, the second overcoating layer 460 can be partially formed in a portion of the first overcoating layer 450, in which the undercut section 400 is formed, thereby reducing the manufacturing cost.

According to another embodiment of the present disclosure, not only can the light extraction efficiency be improved, but also the undercut section can be prevented from becoming a cause of defects, thereby realizing a display device having reliability.

The display device according to various embodiments of the present disclosure can be described as follows.

A display device according to embodiments of the present disclosure can include a substrate, a plurality of driving chips disposed on the substrate, a plurality of light-emitting elements disposed on the driving chip and being electrically connected to each driving chip, an optical insulating layer covering the plurality of light-emitting elements, a first overcoating layer disposed on the optical insulating layer, and a second overcoating layer disposed on the first overcoating layer, and a refractive index of the first overcoating layer can be lower than a refractive index of the second overcoating layer.

According to various embodiments of the present disclosure, the first overcoating layer can cover at least an area in which the plurality of light-emitting elements are disposed.

According to various embodiments of the present disclosure, the first overcoating layer can include a first polymer insulating material having a plurality of scattering particles dispersed therein, and the second overcoating layer can be configured with a second polymer insulating material.

According to various embodiments of the present disclosure, the plurality of scattering particles can include hollow silica.

According to various embodiments of the present disclosure, the first polymer insulating material can include an organosiloxane resin, and the second polymer insulating material can include an acrylic resin.

According to various embodiments of the present disclosure, the second overcoating layer can include an extension portion protruding into a lower area of an edge portion of the first overcoating layer.

According to various embodiments of the present disclosure, the extension portion can be recessed toward an inner side further than an outer end portion of the first overcoating layer.

According to various embodiments of the present disclosure, the plurality of light-emitting elements can include a micro light-emitting element.

According to various embodiments of the present disclosure, the first overcoating layer and the second overcoating layer can be in contact with each other.

A display device according to embodiments of the present disclosure can include a substrate, a plurality of driving chips disposed on the substrate, a plurality of light-emitting elements disposed on the driving chip and being electrically connected to each driving chip, an optical insulating layer covering the plurality of light-emitting elements, a first overcoating layer positioned on the optical insulating layer and including an undercut section formed along an edge portion thereof, and a second overcoating layer filling the undercut section.

According to various embodiments of the present disclosure, the second overcoating layer can surround the edge portion of the first overcoating layer, which includes the undercut section.

According to various embodiments of the present disclosure, the undercut section can be positioned at an inner side further than an outer end portion of the second overcoating layer.

According to various embodiments of the present disclosure, the undercut section can be recessed toward an inner side further than an outer end portion of the first overcoating layer.

According to various embodiments of the present disclosure, the undercut section can be disposed along a lower surface of the edge portion of the first overcoating layer.

According to various embodiments of the present disclosure, the first overcoating can include a lower surface, an upper surface opposite to the lower surface, a side surface connecting the lower surface and the upper surface, and an inclined surface inclined from the side surface toward the lower surface, and the undercut section can be a space between the inclined surface and the optical insulating layer.

According to various embodiments of the present disclosure, the second overcoating layer can be in contact with the upper surface, the side surface, and the inclined surface of the first overcoating layer.

According to various embodiments of the present disclosure, the second overcoating layer can be in contact with the side surface, and the inclined surface of the first overcoating layer.

According to various embodiments of the present disclosure, a refractive index of the first overcoating layer can be lower than a refractive index of the second overcoating layer.

According to various embodiments of the present disclosure, the first overcoating layer can include a first polymer insulating material having a plurality of scattering particles dispersed therein, and the second overcoating layer can be configured with a second polymer insulating material.

According to various embodiments of the present disclosure, the first polymer insulating material can include an organosiloxane resin, and the plurality of scattering particles can include hollow silica.

According to various embodiments of the present disclosure, the plurality of light-emitting elements can include a micro light-emitting element.

According to various embodiments of the present disclosure, the plurality of light-emitting elements can include a micro light-emitting element having a vertical structure.

According to various embodiments of the present disclosure, the display device can further include a bank on which the plurality of light-emitting elements are disposed, a first electrode disposed between the bank and one side of each light-emitting element and electrically connected to the plurality of pixel driving circuits, and a second electrode disposed on another side of each light-emitting element and opposite to the first electrode.

According to various embodiments of the present disclosure, each light-emitting element can be electrically connected to the first electrode by eutectic bonding.

While the embodiments of the present disclosure have been described in detail with reference to the accompanying drawings, it should be understood by a person skilled in the art that the present disclosure is not necessarily limited to the above embodiments, and the above embodiments can be modified without departing from the technical idea of the present disclosure. Accordingly, the embodiments disclosed in the present disclosure are not intended to limit the technical idea of the present disclosure but to explain the technical idea of the present disclosure, and the scope of the technical idea of the present disclosure is not limited by these embodiments. Therefore, it should be understood that the embodiments described above are given only as an example in all respects but not for a limiting purpose.

What is claimed is:

1. A display device comprising:
a substrate;
a plurality of driving chips disposed on the substrate;
a plurality of light-emitting elements disposed on one of the plurality of driving chips and being electrically connected to the one of the plurality of driving chips;
an optical insulating layer covering the plurality of light-emitting elements;
a first overcoating layer disposed on the optical insulating layer; and
a second overcoating layer disposed on the first overcoating layer,
wherein a refractive index of the first overcoating layer is lower than a refractive index of the second overcoating layer.

2. The display device of claim 1, wherein the first overcoating layer covers at least an area in which the plurality of light-emitting elements are disposed.

3. The display device of claim 1, wherein the first overcoating layer includes a first polymer insulating material having a plurality of scattering particles dispersed therein, and
wherein the second overcoating layer includes a second polymer insulating material.

4. The display device of claim 3, wherein the plurality of scattering particles include hollow silica.

5. The display device of claim 3, wherein the first polymer insulating material includes an organosiloxane resin, and
wherein the second polymer insulating material includes an acrylic resin.

6. The display device of claim 1, wherein the second overcoating layer includes an extension portion protruding into a lower area of an edge portion of the first overcoating layer.

7. The display device of claim 6, wherein the extension portion is recessed toward an inner side further than an outer end portion of the first overcoating layer.

8. The display device of claim 1, wherein the plurality of light-emitting elements include at least one micro light-emitting element.

9. The display device of claim 1, wherein the first overcoating layer and the second overcoating layer are in contact with each other.

10. A display device comprising:
a substrate;
a plurality of driving chips disposed on the substrate;
a plurality of light-emitting elements disposed on one of the plurality of driving chips and being electrically connected to the one of the plurality of driving chips;
an optical insulating layer covering the plurality of light-emitting elements;
a first overcoating layer positioned on the optical insulating layer and including an undercut section formed along an edge portion thereof; and
a second overcoating layer filling the undercut section.

11. The display device of claim 10, wherein the second overcoating layer surrounds the edge portion of the first overcoating layer, which includes the undercut section.

12. The display device of claim 10, wherein the undercut section of the first overcoating layer is positioned at an inner side further than an outer end portion of the second overcoating layer.

13. The display device of claim 10, wherein the undercut section of the first overcoating layer is recessed toward an inner side further than an outer end portion of the first overcoating layer.

14. The display device of claim 10, wherein the undercut section of the first overcoating layer is disposed along a lower surface of the edge portion of the first overcoating layer.

15. The display device of claim 10, wherein the first overcoating includes:
a lower surface;
an upper surface opposite to the lower surface;
a side surface connecting the lower surface and the upper surface; and
an inclined surface inclined from the side surface toward the lower surface, and
wherein the undercut section of the first overcoating layer is a space between the inclined surface and the optical insulating layer.

16. The display device of claim 15, wherein the second overcoating layer is in contact with the upper surface, the side surface, and the inclined surface of the first overcoating layer.

17. The display device of claim 15, wherein the second overcoating layer is in contact with the side surface, and the inclined surface of the first overcoating layer.

18. The display device of claim 10, wherein a refractive index of the first overcoating layer is lower than a refractive index of the second overcoating layer.

19. The display device of claim 18, wherein the first overcoating layer includes a first polymer insulating material having a plurality of scattering particles dispersed therein,
wherein the second overcoating layer includes a second polymer insulating material, and
wherein the first polymer insulating material includes an organosiloxane resin, and the plurality of scattering particles include hollow silica.

20. The display device of claim 10, wherein the plurality of light-emitting elements include at least one micro light-emitting element.
